(19) United States
(12) Patent Application Publication
(10) Pub. No.: US 2025/0048630 A1
(43) Pub. Date: Feb. 6, 2025

(54) SEMICONDUCTOR STRUCTURES AND FABRICATION METHODS THEREOF

(71) Applicant: Yangtze Memory Technologies Co., Ltd., Wuhan (CN)

(72) Inventors: Xiaoxin Liu, Wuhan (CN); ZongLiang Huo, Wuhan (CN)

(21) Appl. No.: 18/529,848

(22) Filed: Dec. 5, 2023

(30) Foreign Application Priority Data
Aug. 1, 2023 (CN) 202310962543.0

(51) Int. Cl. H10B 43/27; H01L 23/00; H01L 25/065; H01L 25/18; H10B 43/10; H10B 43/35; H10B 80/00

(52) U.S. Cl. CPC H10B 43/27; H01L 24/08; H01L 25/0657; H01L 25/18; H10B 43/10; H10B 43/35; H10B 80/00; H01L 2224/08145; H01L 2924/1431; H01L 2924/14511

(57) ABSTRACT

The present disclosure provides a semiconductor structure and a fabrication method thereof. The semiconductor structure includes isolating structures and channel structures that are disposed alternately in a second direction, and the channel structure includes two charge storage sections disposed to be spaced from each other in a third direction and a common layer located between the two charge storage sections. The charge storage section includes a plurality of sub charge storage sections disposed to be spaced from each other in the first direction, and in the first direction every two adjacent sub charge storage sections are spaced from each other by a gate dielectric layer. Charges stored in the sub charge storage section are isolated from the sub charge storage sections corresponding to different gate line layers. The semiconductor structure is applied to a three-dimensional memory to enable data read and write operations.

### REFERENCE TO RELATED APPLICATIONS

This application claims priority to and the benefit of Chinese Patent Application 202310962543.0, filed on Aug. 1, 2023, which is hereby incorporated by reference in its entirety.

### TECHNICAL FIELD

The present disclosure relates to the field of semiconductor chip technology, and particularly to a semiconductor structure and a fabrication method thereof.

### BACKGROUND

As feature sizes of memory cells approach a lower process limit, planar processes and fabrication techniques become challenging and costly. As such, the memory density for 2D or planar memory cells approaches an upper limit. In order to address the limitations suffered by the 2D or planar NAND flashes, memories having three-dimensional structures (3D NAND memories) have been developed in the industry to increase their memory density by disposing memory cells in three dimensions on a substrate.

### BRIEF DESCRIPTION OF DRAWINGS

In order to explain technical solutions in the present disclosure more clearly, accompanying drawings required by examples of the present disclosure will be described briefly hereafter. It is obvious that the drawings described below are only for some examples of the present disclosure and other drawings can be obtained according to those drawings by those skilled in the art. Moreover, the accompanying drawings described below may be considered as schematic diagrams and mean no limitation on actual sizes of a product, the actual flow of a method, actual timing of signals involved in examples of the present disclosure.

FIG. 1 is a stereoscopic structural diagram of a three-dimensional memory in accordance with some examples;

FIG. 2 is a cross-sectional view of a three-dimensional memory in accordance with some examples;

FIG. 3 is a cross-sectional view of a memory cell string in the three-dimensional memory shown in FIG. 1 taken along the cut line AA′;

FIG. 4 is an equivalent circuit diagram of a memory cell string;

FIG. 5 is a cross-sectional diagram of a semiconductor structure in accordance with some examples;

FIG. 6 is a partially enlarged diagram of the portion A in FIG. 5;

FIG. 7 is a structural diagram of a semiconductor structure in accordance with some examples;

FIG. 8 is a cross-sectional view along the direction B-B in FIG. 7;

FIG. 9 is a structural diagram of a semiconductor structure in accordance with some examples;

FIG. 10 is cross-sectional view along the C-C direction of FIG. 9;

FIG. 11A is the first stage of a fabrication method of a semiconductor structure in accordance with some examples;

FIG. 11B is the second stage of a fabrication method of a semiconductor structure in accordance with some examples;

FIG. 11C is the third stage of a fabrication method of a semiconductor structure in accordance with some examples;

FIG. 11D is the fourth stage of a fabrication method of a semiconductor structure in accordance with some examples;

FIG. 11E is the fifth stage of a fabrication method of a semiconductor structure in accordance with some examples;

FIG. 11F is the sixth stage of a fabrication method of a semiconductor structure in accordance with some examples;

FIG. 11G is the seventh stage of a fabrication method of a semiconductor structure in accordance with some examples;

FIG. 11H is the eighth stage of a fabrication method of a semiconductor structure in accordance with some examples;

FIG. 11I is the ninth stage of a fabrication method of a semiconductor structure in accordance with some examples;

FIG. 11J is the tenth stage of a fabrication method of a semiconductor structure in accordance with some examples;

FIG. 11K is the eleventh stage of a fabrication method of a semiconductor structure in accordance with some examples;

FIG. 11L is the twelfth stage of a fabrication method of a semiconductor structure in accordance with some examples;

FIG. 11M is the thirteenth stage of a fabrication method of a semiconductor structure in accordance with some examples;

FIG. 12 is the first flow chart of a fabrication method of a semiconductor structure in accordance with some examples;

FIG. 13 is the second flow chart of a fabrication method of a semiconductor structure in accordance with some examples;

FIG. 14 is the third flow chart of a fabrication method of a semiconductor structure in accordance with some examples;

FIG. 15 is the fourth flow chart of a fabrication method of a semiconductor structure in accordance with some examples;

FIG. 16 is a block diagram of a memory system in accordance with some examples; and

FIG. 17 is a block diagram of a memory system in accordance with some other examples.

### DETAILED DESCRIPTION

Technical solutions in some examples of the present disclosure will be described below clearly and completely with reference to accompanying drawings. It is obvious that the examples to be described are only some, not all, examples of the present disclosure. All other examples obtained by those skilled in the art based on the examples provided in the present disclosure fall within the scope claimed by the present disclosure.

In the description of the present disclosure, it should be understood that orientation and position relationships indicated by terms “upper”, “lower”, “left”, “right”, “top”, “bottom”, “inner” and “outer” are those based on the drawings and only for the purpose of describing and simplifying the description. There is no indication or implication that the devices or elements referred to must have any particular orientations and positions, or be constructed or operated in any particular orientations and positions. Therefore, they should not be understood as limitation for the present disclosure.

In the whole specification and claims, the term “include” should be interpreted to be open and inclusive, i.e. to have the meaning of “include or comprise, but not limited to”, unless indicated otherwise in the context. In the description of the specification, terms “one example”, “some examples”, “illustrative examples”, “illustratively” or “some implementations” are intended to indicate that the particular features, structures, materials or characteristics related to the example(s) or implementation(s) are included in at least one example or implementation of the present disclosure. The expression by the above-mentioned terms may not necessarily refer to one and the same example or implementation. Moreover, the particular features, structures, materials or characteristics may be included in one or more examples or implementations in any suitable way.

Hereafter, the terms “first”, “second” etc. are only used for the purpose of description and should not be understood to indicate or imply relative importance or to designate the number of the referenced technical features implicitly. Therefore, a feature being qualified by “first” or “second” may indicate explicitly or implicitly that one or more features are included. In description of examples of the present disclosure, the expression of “a plurality of” means two or more unless otherwise specified.

In description of some examples, terms “couple” and “connect” as well as their derivative expressions may be used. For example, in description of some examples, the term “connect” may be used to indicate that two or more components are in direct physical or electrical contact with each other. For another example, in description of some examples, the term “couple” may be used to indicate that two or more components are in direct physical or electrical contact. However, the term “couple” may also indicate that two or more components are not in direct contact with each other, but still cooperate or interact. Examples of the present disclosure are not necessarily limited by what is described herein.

The use of “configured to” means an open and inclusive meaning and is not intended to exclude that a device is suitable for additional tasks or procedures or configured to perform additional tasks or procedures.

In the content of the present disclosure, the terms “on” and “over” should be interpreted in the broadest manner such that “on” not only means “directly on” something but also includes the meaning of “on” something with an intermediate feature or a layer therebetween, and that “over” not only indicates the meaning of “over” something but also includes the meaning of “over” something with no intermediate feature or layer therebetween (i.e., directly on something).

Example implementations are described herein with reference to cross-sectional views and/or plan views as idealized illustrative figures. In the figures, thicknesses of layers and regions are exaggerated for clarity. Therefore, it can be appreciated that deviation from the shapes of the figures may be caused by, for example, manufacturing processes and/or tolerances. Therefore, example implementations should not be interpreted to be limited to the shapes of the regions illustrated herein, but include shape deviation caused by, for example, manufacturing. For example, an etched region of a rectangular shape usually has curved features. Therefore, the regions shown in the figures are illustrative in nature and their shapes are not intended to depict actual shapes of regions of a device and also not intended to limit the scope of example implementations.

As used herein, the term “substrate” refers to a material onto which subsequent material layers may be added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

The term “three-dimensional memory” refers to a semiconductor structure formed of memory cell transistor strings (referred to as “memory cell strings” herein, for example, NAND memory cell strings) that are arranged in an array on the main surface of a substrate or a source layer and extend in a direction perpendicular to the substrate or the source layer. As used herein, the term “vertical/vertically” means being perpendicular to the main surface of the substrate or the source layer (i.e., a lateral surface) nominally.

As the number of layers stacked in a memory stack structure of a semiconductor structure increases, the thicknesses of the gate dielectric layer and the gate line layer therein are reduced, which may cause increased interaction between memory cells and charge diffusion of channel structures and in turn affect the memory performance of the semiconductor structure.

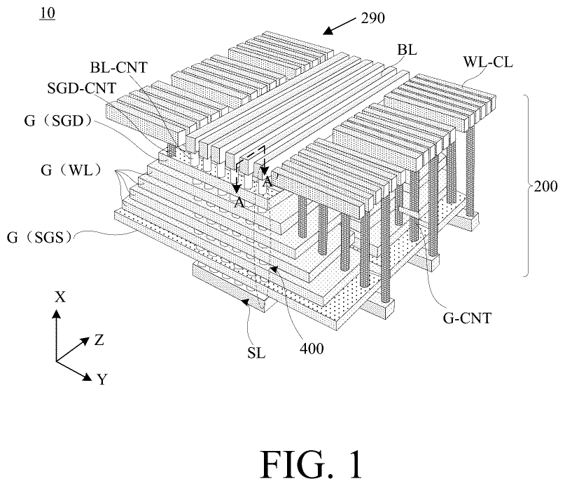

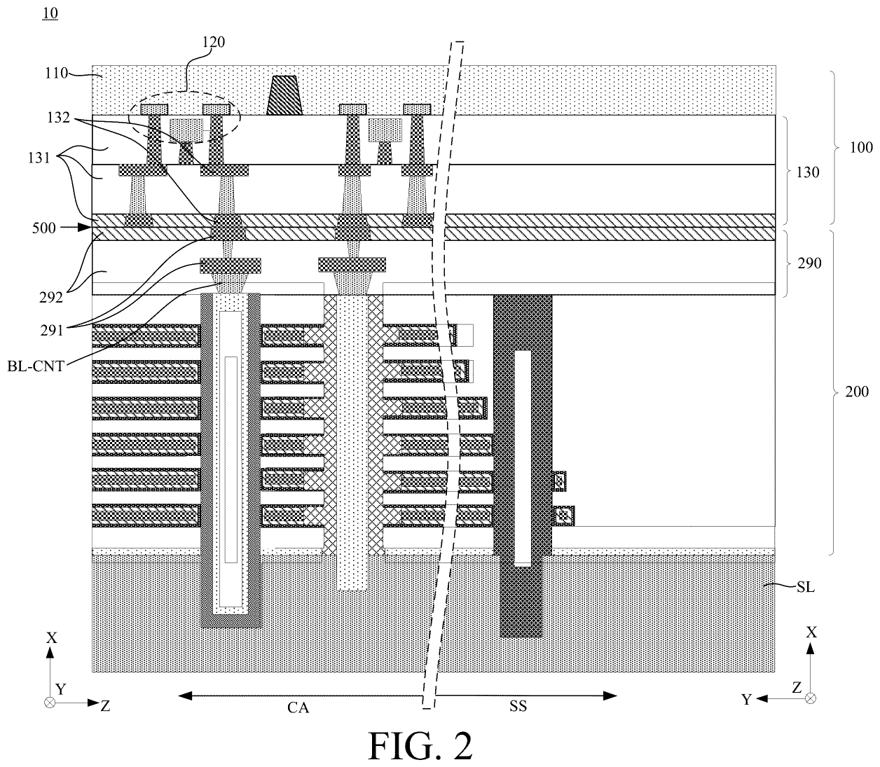

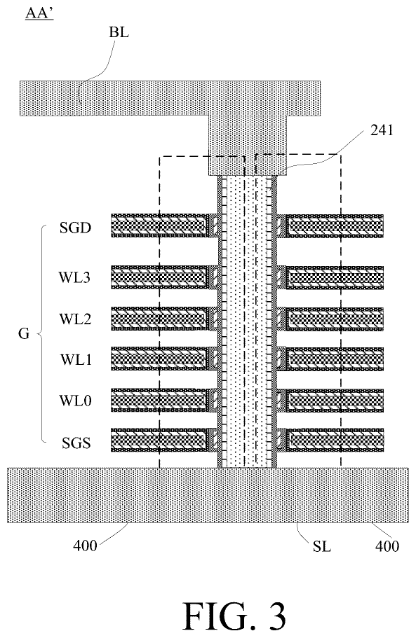

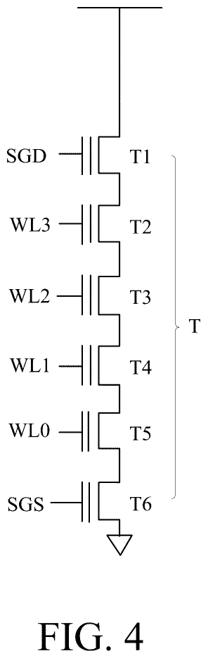

FIG. 1 is a stereoscopic structural diagram of a three-dimensional memory provided by some examples of the present disclosure, FIG. 2 is a cross-sectional view of the three-dimensional memory, FIG. 3 is a cross-sectional view of a memory cell string in the three-dimensional memory in FIG. 1 taken along the cut line AA′, and FIG. 4 is an equivalent circuit diagram of the memory cell string in FIG. 3.

It is to be noted that, in FIGS. 1 and 2, the three-dimensional memory 10 extends in the Y-Z plane. The first direction X is perpendicular to the Y-Z plane, and the second direction Y and the third direction Z are, for example, two orthogonal directions in the plane in which the semiconductor structure 200 is located, for example, the plane, in which the source layer SL is located. The second direction Y is, for example, the direction, in which WLs extend and the third direction Z is, for example, the direction, in which BLs extend. Here, a direction indicated by an arrow and its opposite direction may be considered as the same direction. The same definitions about directions may be used in all the drawings in the present specification.

As used in the present disclosure, whether a component (e.g., a layer, structure or device) is located “on”, “over” or “under” another component (e.g., another layer, structure or device) in a semiconductor structure (e.g., a three-dimensional memory) is determined with respect to the substrate or source layer of the semiconductor structure in the first direction X when the substrate or source layer is at the lowest plane of the semiconductor structure in the first direction X. In the content of the whole application, the same concepts are used to describe spatial relationship.

In order to illustrate structures of the device more clearly, the view of an array area CA and the view of a staircase area SS are shown in FIG. 2, the former is based on the coordinate system on the left and the latter is based on the coordinate system on the right. That is, the view of the array area CA shows the cross-sectional structure along the Z direction and the view of the staircase area SS shows the cross-sectional structure along the Y direction.

With reference to FIGS. 1 and 2, some examples of the present disclosure provide a three-dimensional memory 10. The three-dimensional memory 10 may include a semiconductor structure 200, a source layer SL coupled with the semiconductor structure 200 and a peripheral device 100 coupled with the semiconductor structure 200. The peripheral device 100 may be disposed on a side of the semiconductor structure 200 away from the source layer SL.

The source layer SL may include a semiconductor material, such as single crystal silicon, single crystal germanium, a III-V compound semiconductor material, a II-VI compound semiconductor material or any other suitable semiconductor material. The source layer SL may be doped partially or entirely. Illustratively, the source layer SL may include a doped region that is doped with a p-type dopant. The source layer SL may also include an undoped region.

The semiconductor structure 200 may include memory cell transistor strings (hereafter referred to as “memory cell strings”, for example, NAND memory cell strings) 400 disposed in an array. The source layer SL may be coupled with the source terminals of a plurality of memory cell strings 400.

Specifically, with reference to FIGS. 3 and 4, the memory cell string 400 may include a plurality of transistors T. A transistor T (e.g., any of T1˜T6 in FIG. 4) may be disposed as a memory cell and these transistors T are connected to form the memory cell string. The transistor T (e.g., each transistor T) may be formed of a semiconductor channel 241 and a gate line G surrounding the semiconductor channel 241. Here, the gate line G may be configured to control the on/off state of the transistor.

It is to be noted that the numbers of transistors in FIGS. 1 to 4 are only illustrative, and the memory cell string in a three-dimensional memory provided by examples of the present disclosure may include any other number of transistors, for example, 4, 16, 32 or 64.

Further, along the first direction X, the lowermost gate line of a plurality of gate lines G (e.g., the gate line of the plurality of gate lines G closest to the source layer SL) may be constructed as a source select gate SGS that is configured to control the on/off state of a transistor T6 and in turn the on/off state of the channel at the source of a memory cell string 400. The uppermost gate line of the plurality of gate lines G (e.g., the gate line of the plurality of gate lines G furthest from the source layer SL) may be constructed as a drain select gate SGD that is configured to control the on/off state of a transistor T1 and in turn the on/off state of the channel at the drain of a memory cell string 400. The middle gate lines of the plurality of gate lines G may be constructed as a plurality of word lines WL including, for example, a word line WL0, a word line WL1, a word line WL2 and a word line WL3. By applying different voltages on the word lines WL, the memory cells (e.g., transistors T) in the memory cell strings 400 can be written, read and erased.

With continued reference to FIGS. 1 and 2, in some examples, the semiconductor structure 200 may further include an array interconnection layer 290. The array interconnection layer 290 may be coupled with the memory cell strings 400. The array interconnection layer 290 may include drains of the memory cell strings 400 (i.e., bit lines BL) that are coupled with semiconductor channels of transistors T in at least one of the memory cell strings 400.

The array interconnection layer 290 may include one or more first interlayer insulating layers 292 and may further include a plurality of contacts insulated by the first interlayer insulating layer 292, such as bit line contacts BL-CNT coupled with bit lines BL and a drain select gate contact SGD-CNT coupled with drain select gate SGD. The array interconnection layer 290 may further include one or more first interconnection conductor layers 291. The first interconnection conductor layer 291 may include a plurality of connecting lines, such as bit lines and word line connecting lines WL-CL coupled with word lines WL. The contacts and the first interconnection conductor layer 291 may include conductive materials such as any combination of one or more of tungsten, cobalt, copper, aluminum and metal silicides, or may include any other suitable materials. The first interlayer insulating layer 292 may include an insulating material, such as any combination of one or more of silicon oxide, silicon nitride and an insulating material having a high dielectric constant, or may include any other suitable materials.

The peripheral device 100 may include peripheral circuits. The peripheral circuits are configured to control and sense the array devices. The peripheral circuits may be any suitable digital, analog, and/or mixed-signal control and sensing circuits, including, but not limited to, page buffers, decoders (e.g., row decoders and column decoders), readout amplifiers, drivers (e.g., word line drivers), charge pumps, current or voltage references, or any active or passive components of a circuit (e.g., transistors, diodes, resistors or capacitors), that are used to support operations (or functions) of the array devices. The peripheral circuits may also include any other circuits compatible with advanced logic processes including logic circuits (e.g., processors and programmable logic devices PLD) or memory circuits (e.g., static random access memories SRAM).

Specifically, in some examples, the peripheral device 100 may include a substrate 110, transistors 120 disposed on the substrate 110 and a peripheral interconnection layer 130 disposed on the substrate 110. The peripheral circuit may include the transistors 120.

The substrate 110 may include single crystal silicon or any other suitable material such as a thin film of silicon germanium, germanium or silicon on insulator.

The peripheral interconnection layer 130 is coupled with the transistors 120 to enable transmission of electrical signals therebetween. The peripheral interconnection layer 130 may include one or more second interlayer insulating layers 131 and may further include one or more second interconnection conductor layer 132. Different second interconnection conductor layers 132 may be coupled with each other through contacts. The contacts and the second interconnection conductor layers 132 may include conductive materials such as any combination of one or more of tungsten, cobalt, copper, aluminum and metal silicides, or may comprise any other suitable materials. The second interlayer insulating layers 131 includes an insulating material, for example, any combination of one or more of silicon oxide, silicon nitride and an insulating material having a high dielectric constant, or any other suitable materials.

The peripheral interconnection layer 130 may be coupled with the array interconnection layer 290, so that the semiconductor structure 200 may be coupled with the peripheral device 100. Specifically, since the peripheral interconnection layer 130 is coupled with the array interconnection layer 290, the peripheral circuits in the peripheral device 100 can be coupled with the memory cell strings 400 in the semiconductor structure 200 to enable transmission of electrical signals therebetween. In some possible implementations, a bonding interface 500 may be disposed between the peripheral interconnection layer 130 and the array interconnection layer 290. Through the bonding interface 500, the peripheral interconnection layer 130 and the array interconnection layer 290 may be bonded and coupled to each other.

The semiconductor structure 200 provided in examples of the present disclosure may serve as an entire three-dimensional memory 10 or as a part of a three-dimensional memory 10. Illustratively, the three-dimensional memory 10 may include the semiconductor structure 200 and the peripheral device 100 described above that are electrically connected with each other.

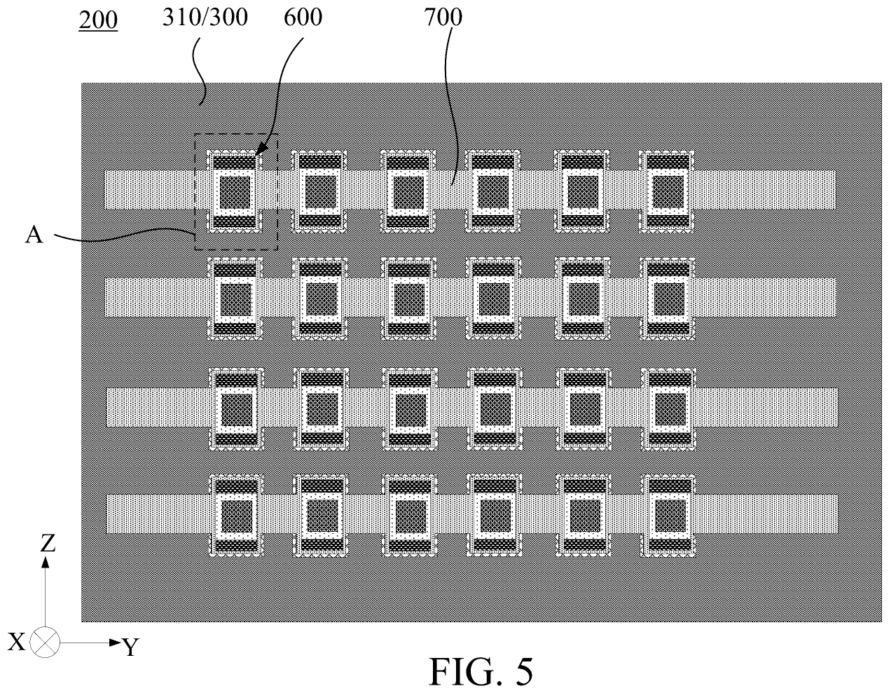

FIG. 5 is a cross-sectional diagram of a semiconductor structure in accordance with some examples. With reference to FIG. 5, the present disclosure provides a semiconductor structure 200 that includes a memory stack structure 300, channel structures 600 and isolating structures 700.

In some examples, the memory stack structure 300 may be disposed on the source layer SL (as shown in FIG. 2).

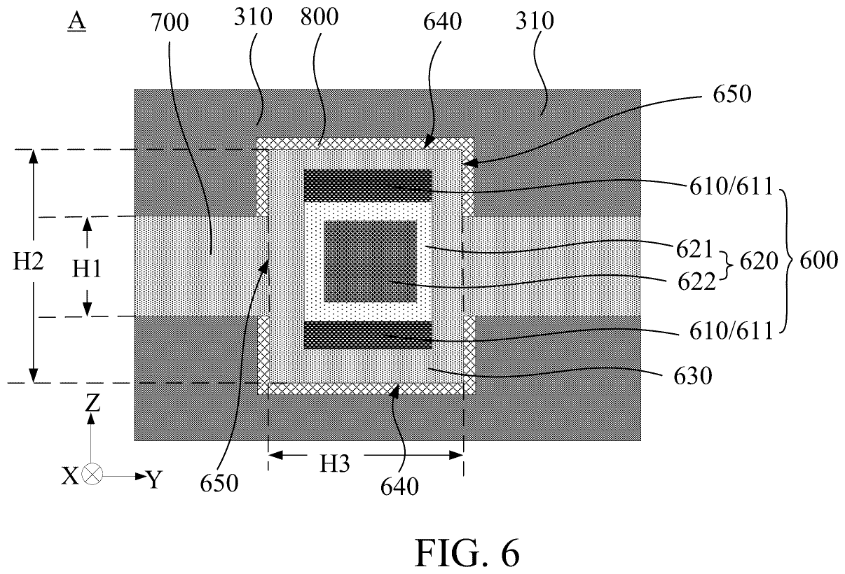

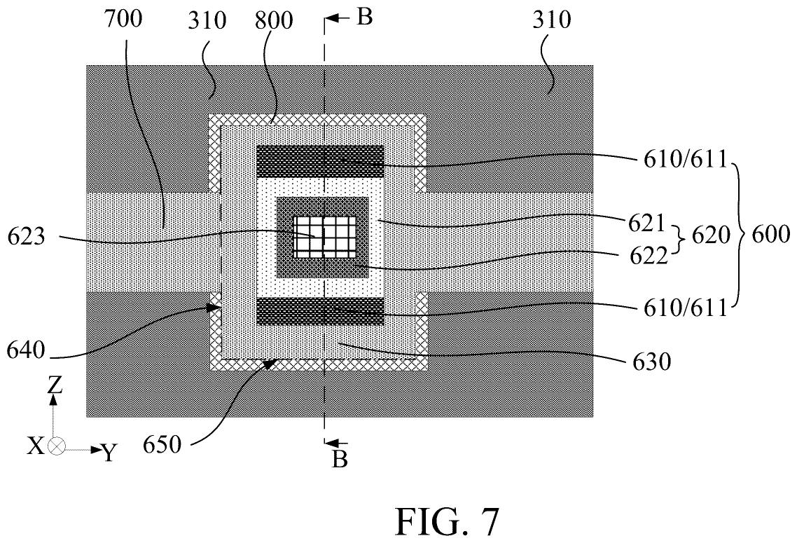

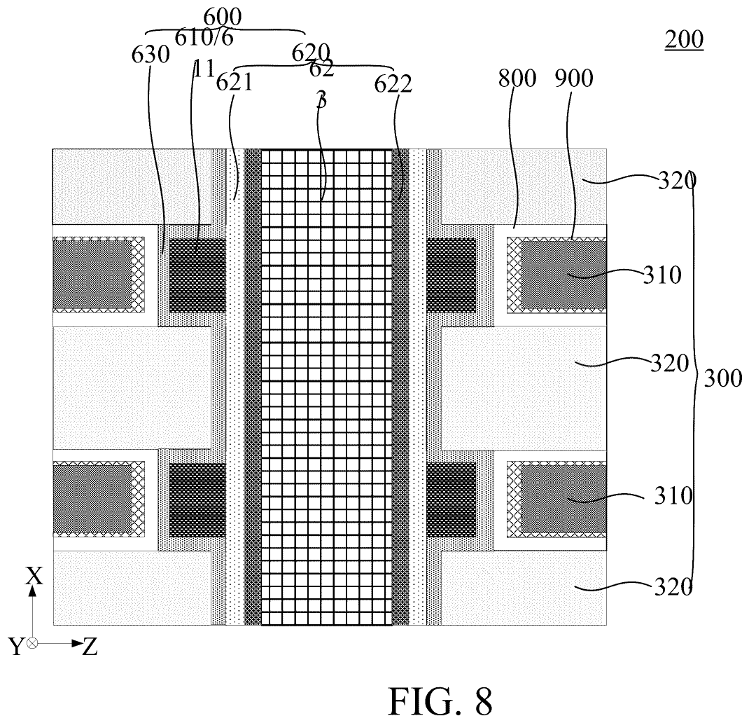

FIG. 6 is a partially enlarged view of the portion A in FIG. 5, FIG. 7 is a structural diagram of a semiconductor structure in accordance with some examples and FIG. 8 is a cross-sectional diagram taken along the direction B-B in FIG. 7.

With reference to FIG. 8, the memory stack structure 300 includes gate line layers 310 and gate dielectric layers 320 stacked alternately in the first direction X. Here, a plurality of gate line layers 310 and a plurality of gate dielectric layers 320 may be included in the memory stack structure 300 and only two gate line layers 310 and a gate dielectric layer 320 are illustrated in FIG. 8.

In some examples, the first direction X may be perpendicular to the gate dielectric layer 320. Here, the term “perpendicular” includes the meaning of “perpendicular absolutely” and “perpendicular approximately” and the latter may have an acceptable deviation within a range, for example, within 5°.

In some implementations, the gate line layer 310 may be made of a conductive material, for example, at least one of tungsten, cobalt, copper, aluminum, doped silicon and silicide. The gate dielectric layer 320 may be made of an insulating material, for example, at least one of silicon oxide, silicon nitride and silicon oxynitride.

The channel structure 600 may penetrate through the memory stack structure 300 in the first direction X and here penetrates through a plurality of gate line layers 310 and a plurality of gate dielectric layers 320.

With reference to FIGS. 6 to 8, the channel structure 600 may include two charge storage sections 610 disposed to be spaced from each other in the third direction Z and a common layer 620 located between the two charge storage sections 610. The charge storage section 610 is configured to store electrons, so that the memory cell has respective threshold voltage. Illustratively, the charge storage section 610 may include at least one of silicon oxide, silicon oxynitride, silicon and a metal oxide.

Here, the channel structure 600 may include two charge storage sections 610 and a common layer 620 which can be shared by the two charge storage sections 610 to increase the number of the charge storage sections 610 in the channel structure 600. A charge storage section 610 may be configured to form a memory cell string 400. Therefore, by disposing two charge storage sections 610 in the channel structure 600, the number of memory cell strings 400 in the channel structure 600 may be increased, thereby increasing storage density of the semiconductor structure 200.

Additionally, the two charge storage sections 610 are located on the two opposite sides of the common layer 620 in the third direction Z and no charge storage sections 610 are disposed on the two opposite sides of the common layer 620 in the second direction Y, so that the size of the channel structure 600 in the second direction Y may be reduced to increase the density of the channel structures 600 and in turn the storage density of the semiconductor structure 200.

Illustratively, both the second direction Y and the third direction Z may be parallel to the gate dielectric layer 320. Here, the term “parallel” includes the meaning of “parallel absolutely” and “parallel approximately” and the latter may have an acceptable deviation range that is within 5°. Here, both the second direction Y and the third direction Z are parallel to the gate dielectric layer 320.

Illustratively, the second direction Y and the third direction Z are perpendicular to each other.

With reference to FIG. 8 again, the charge storage section 610 includes a plurality of sub charge storage sections 611 that are disposed to be spaced from each other in the first direction X and correspond to one of the plurality of gate line layers 310, respectively. Here, the term “correspond” can be understood that a projection of a sub charge storage section 611 in the direction parallel to the third direction Z covers at least part of a gate line layer 310. Here, the direction parallel to the third direction Z may be the direction parallel to and directing to the gate line layer 310.

Here, in the first direction X, every two adjacent sub charge storage sections 611 are spaced from each other by a gate dielectric layer 320.

Here, in the channel structure 600, a sub charge storage section 611 in the charge storage section 610 may be aligned with a sub charge storage section 611 in another charge storage section 610, that is, the orthogonal projection of a sub charge storage section 611 in the charge storage section 610 in the third direction Z and the orthogonal projection of a sub charge storage section 611 in another charge storage section 610 in the third direction Z may cover the same gate line layer 310.

Since two adjacent charge storage sections 611 in the first direction X are disposed to be spaced from each other, charges in the charge storage sections 611 can be inhibited from diffusing in the first direction X, which facilitates formation of a uniform potential field at the sub charge storage sections 611 and thus improve reliability of storage of the sub charge storage sections 611.

Additionally, a sub charge storage section 611 can form a transistor T together with the respective gate line layer 310 and the respective common layer. In related art, the sub charge storage section 611 in a transistor T can store at most 3 bytes. However, in the present disclosure, since two adjacent charge storage sections 611 in the first direction X are isolated from each other, diffusion of charges is inhibited and therefore a sub charge storage section 611 can store more bytes, for example, 4 or 5 bytes, allowing more bytes to be stored in a channel structure 600 and thus improving the storage density of the semiconductor structure.

In the case that a sub charge storage section 611 can store 5 bytes, the semiconductor structure 200 may be applied to a penta-level cell (PLC) memory, while in the case that a sub charge storage section 611 can store 4 bytes, the semiconductor structure 200 may be applied to a quad-level cell (QLC) memory.

Illustratively, the sub charge storage section 611 may include at least one of silicon oxide, silicon oxynitride, silicon and a metal oxide.

With reference to FIG. 5 again, the semiconductor structure 200 may further include isolating structures 700 that penetrate through the memory stack structure 300 in the first direction X. The isolating structure 700 is located between two adjacent channel structures 600 in the second direction Y, that is, the isolating structure 700 and the channel structure 600 are disposed alternately in the second direction Y.

The isolating structure 700 is made of an insulating material to insulate two adjacent channel structures 600 in the second direction Y from each other and reduce interaction therebetween.

Illustratively, the isolating structure 700 may include at least one of an oxide and an insulating material having a high dielectric constant.

With reference to FIG. 6, in the above-described implementations, the width H1 of the isolating structure 700 in the third direction Z is smaller than the width H2 of the channel structure 600 in the third direction Z.

Illustratively, the isolating structure 700 faces the common layer 620 in the second direction Y, and the charge storage section 610 and the isolating structure 700 may be staggered in the second direction Y, so that the width H1 of the isolating structure 700 in the third direction Z is smaller than the width H2 of the channel structure 600 in the third direction Z.

The isolating structure 700 faces the common layers 620 in the second direction Y, so that the orthogonal projection of the isolating structure 700 in the second direction Y may cover at least a part of the common layer 620. Here, the width of the isolating structure 700 in the third direction Z may be smaller than or equal to the width of the common layer 620 in the third direction Z.

Here, the charge storage section 610 and the isolating structure 700 may be staggered in the second direction Y, and the orthogonal projection of the charge storage section 610 in the second direction Y do not overlap the orthogonal projection of the isolating structure 700 in the second direction Y. The charge storage section 610 is disposed to correspond to the gate line layer 310 in both the second direction Y and the third direction Z, so that the detected area between the charge storage section 610 and the gate line layer 310 will be increased, increasing the speed of storage of the charge storage section 610.

With continued reference to FIG. 6, in the above-described implementations, the common layer 620 may include a tunneling layer 621 and a channel layer 622.

In some examples, the channel layer 622 may have a pillar shape and extend through the memory stack structure 300 in the first direction X, and the tunneling layer 621 covers outer wall of the channel layer 622, that is, in the second direction Y, the tunneling layer 621 is located between the channel layer 622 and the isolating structure 700, while in the third direction Z, the tunneling layer 621 is located between the channel layer 622 and the charge storage section 610 or between the channel layer 622 and the gate dielectric layer 320. Illustratively, the tunneling layer 621 may include at least one of silicon oxide or a metal oxide. Illustratively, the channel layer 622 may include at least one of polysilicon or single crystal silicon. With reference to FIG. 6, in some examples, the channel layer 622 may be a solid pillar.

With reference to FIG. 7, in some other examples, the channel layer 622 may also be a hollow pillar, and in this case the common layer 620 may further include a supporting section 623 located inside the channel layer 622, so that the channel layer 622 surrounds the supporting section 623 and the supporting section 623 provides support for the channel structure 600.

Illustratively, the supporting section 623 may include an insulating material, for example, silicon oxide.

With reference to FIG. 6 again, in examples of the present disclosure, the channel structure 600 may further include a insulating layer 630 surrounding the charge storage sections 610 and the common layer 620. The insulating layer 630 may include oxide, an insulating material having a high dielectric constant or any combination thereof. The insulating layer 630 may be formed of the same material as the isolating structure 700.

With continued reference to FIGS. 6 and 7, in examples of the present disclosure, the channel structure 600 includes two first planes 640 opposite to each other in the second direction Y and two second planes 650 opposite to each other in the third direction Z. The first plane 640 is connected to the two second planes 650 on both sides in the second direction Y, and the second plane 650 is connected to the two first planes 640 on both sides in the third direction.

In some examples, both the first plane 640 and the second plane 650 are located on a side of the insulating layer 630 away from the common layer 620. Two charge storage sections 610 are disposed close to the two first planes 640, respectively.

With continued reference to FIGS. 6 and 7, in the above-described implementations, the orthogonal projection of the channel structure 600 in the first direction X has a rectangular shape, i.e. a square shape or an oblong rectangular shape.

The rectangular shape may be a standard rectangular shape, i.e. every two adjacent edges of the rectangular shape form a right angle.

In addition, the rectangular shape may also be an approximate rectangular shape, i.e. two adjacent straight edges of the rectangular shape are perpendicular to each other, but the intersection of the two straight edges form an arc shape.

With reference to FIG. 6, in some examples, the width H2 of the channel structure 600 in the third direction Z is larger than the width H3 of the channel structure 600 in the second direction Y, so that the width of the channel structure 600 in the second direction Y may be reduced to increase the density of channel structures 600 and improve the storage density of the semiconductor structure 200.

With continued reference to FIG. 8, in some examples of the present disclosure, the semiconductor structure 200 may further include high dielectric constant layers 800. The high dielectric constant layer 800 may be located between the gate line layer 310 and the gate dielectric layer 320 and between the gate line layer 310 and the channel structure 600. The high dielectric constant layer 800 may be formed of a material having a high dielectric constant. In the semiconductor industry, a high dielectric constant usually means that the dielectric constant k of a material is higher than the dielectric constant k of silicon dioxide, i.e. higher than 3.9. The high dielectric constant layer 800 may have a dielectric constant of 4.0, 4.6, 5.2, 5.5, 6.0, 6.3, 6.7, 7.2, 8.5, 9.1, 9.8, 10.4, etc. The material of the high dielectric constant layer 800 includes, but not limited to, one or more of aluminum oxide (Al₂O₃), hafnium dioxide (HfO₂), tantalum pentoxide (Ta₂O₅), titanium dioxide (TiO₂), silicon oxynitride (SiOxNy).

Here, portions of the high dielectric constant layer 800 may be located on two opposite surfaces of the gate line layer 310 in the first direction X. Here, the high dielectric constant layer 800 may protect the gate line layer 310 from being oxidized and its performance from being affected.

With reference to FIG. 8, in some examples, the semiconductor structure may further include titanium nitride (TiN) layers 900 and the high dielectric constant layer 800 is located between the TiN layer 900 and gate line layer 310.

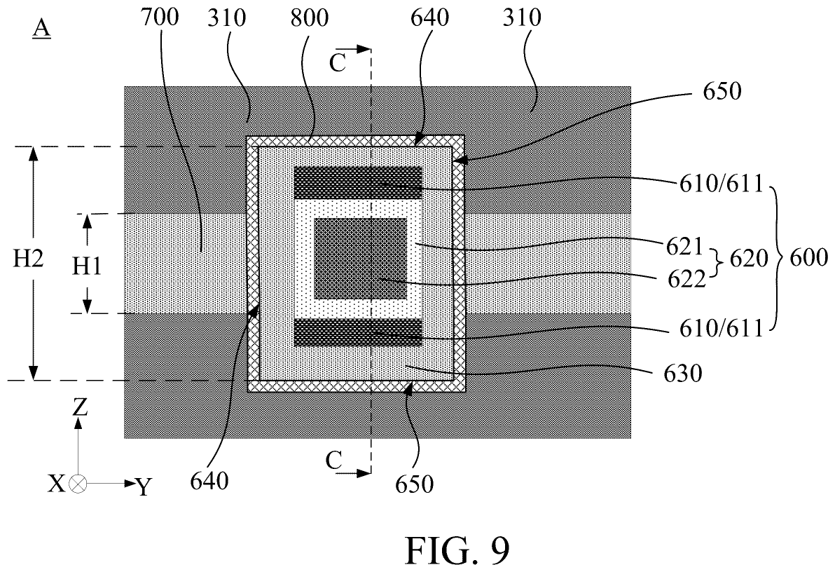

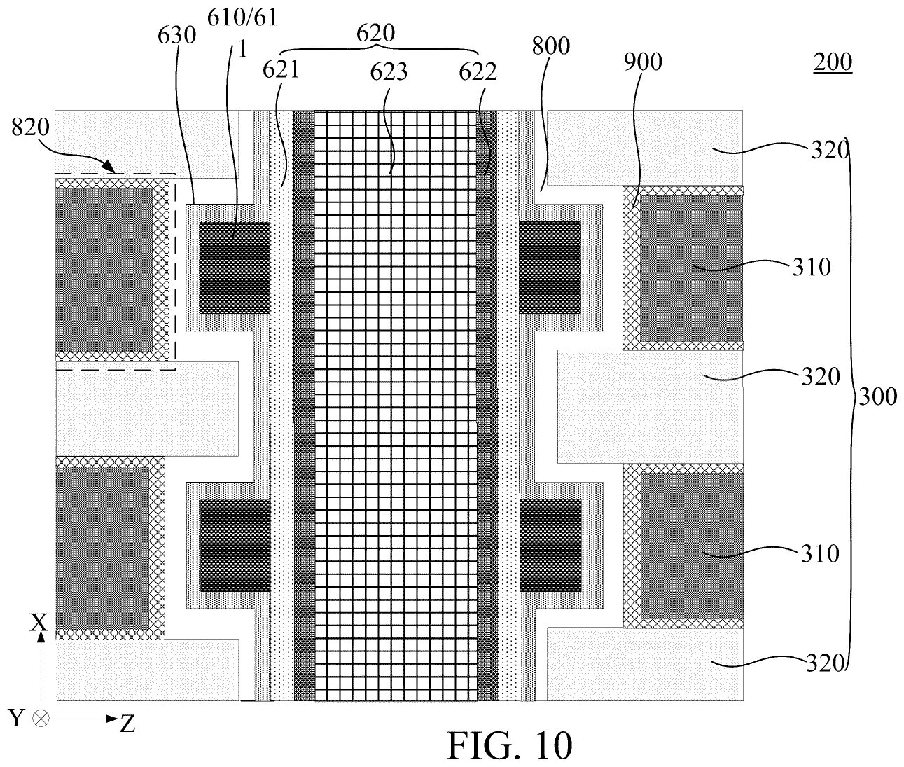

FIG. 9 is a structural diagram of a semiconductor structure in accordance with some examples and FIG. 10 is a cross-sectional diagram taken along the direction C-C in FIG. 9.

With reference to FIGS. 9 and 10, in some other examples, a high dielectric constant layer 800 may surround the channel structure 600 and extend through the memory stack structure 300 in the first direction X. With this configuration, the area of the high dielectric constant layer 800 may be reduced to facilitate more uniform thickness of the high dielectric constant layer 800.

Here, the high dielectric constant layer 800 may be located between the gate line layers 310 and the channel structure 600, between the gate dielectric layers 320 and the channel structure 600 and between the isolating structures 700 and channel structure 600.

In this example, the orthogonal projection of the high dielectric constant layer 800 in the third direction Z may cover the gate dielectric layers 320 and the gate line layers 310.

However, in some other examples, the orthogonal projection of the high dielectric constant layer 800 may only cover the gate line layers 310.

Based on the semiconductor structure 200 provided in some examples described above, the present disclosure further provides a fabrication method of a semiconductor structure.

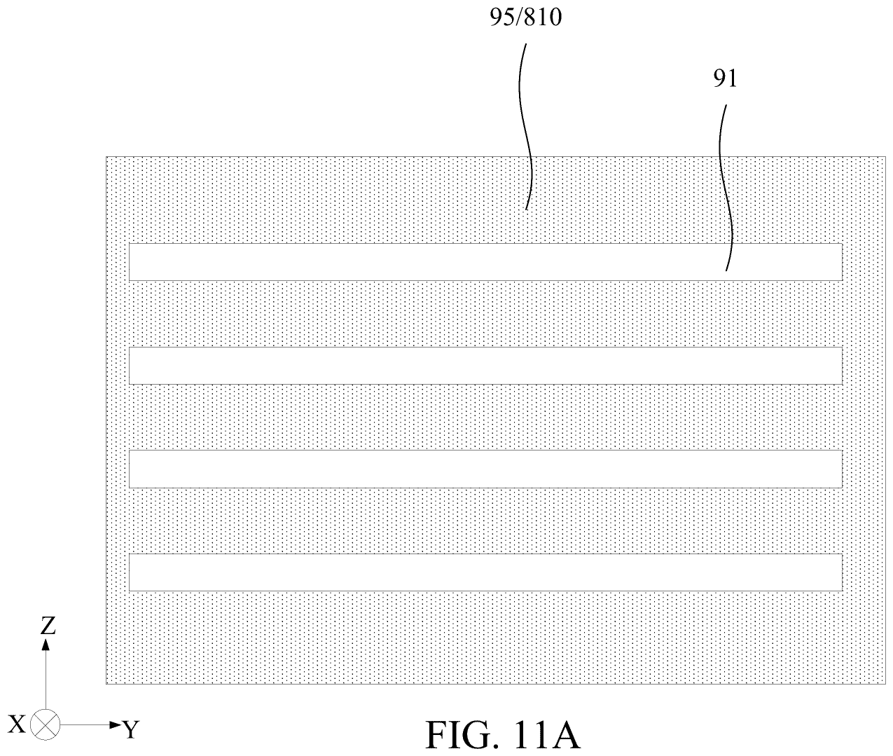

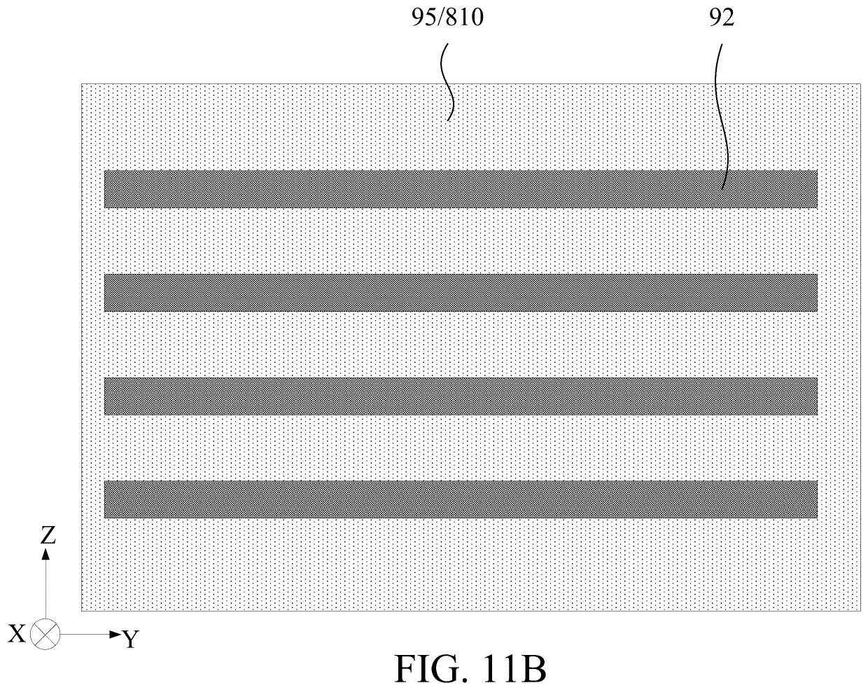

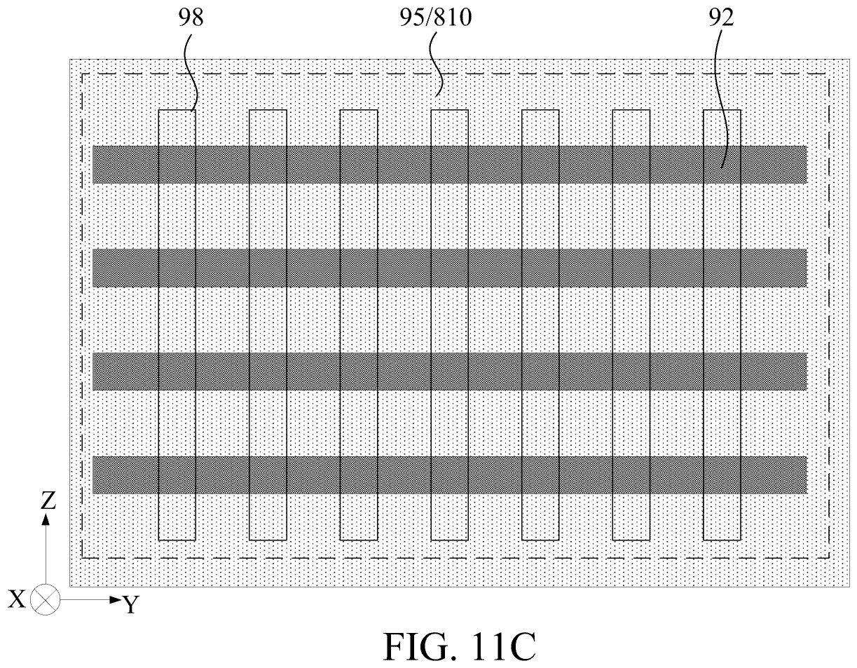

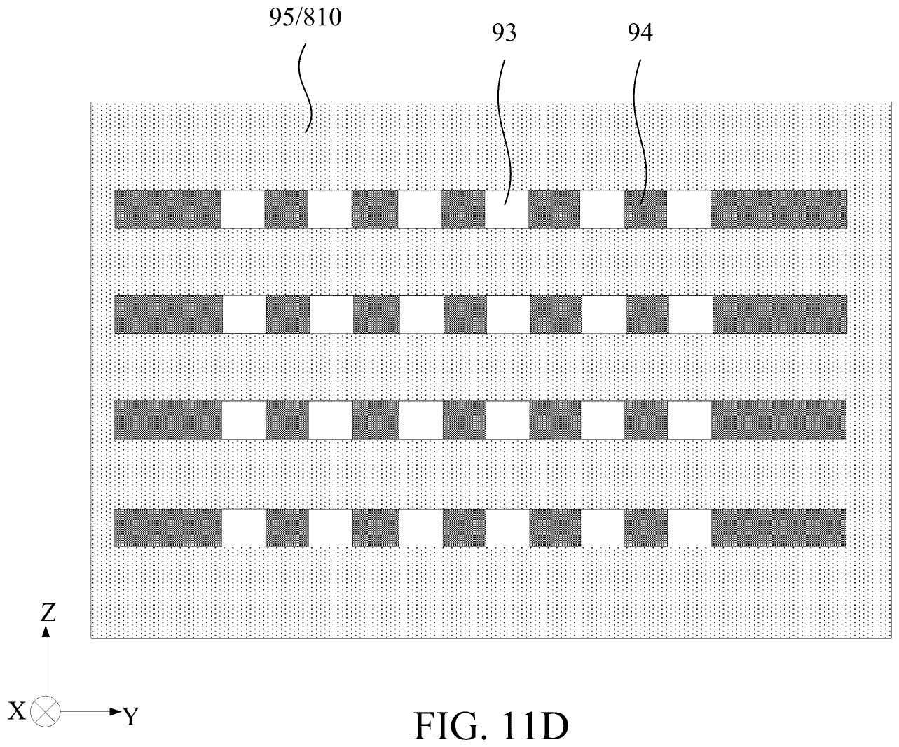

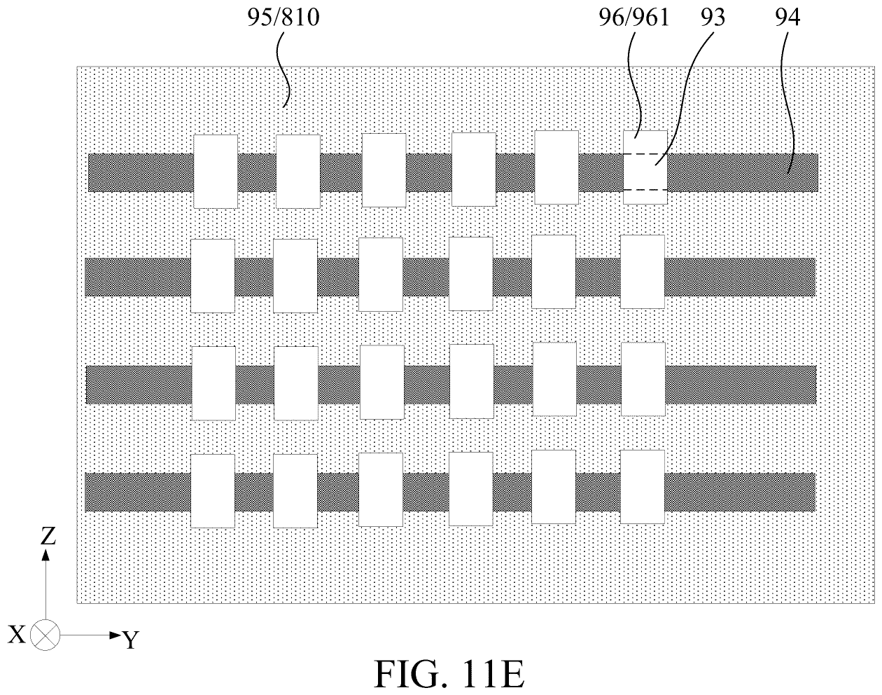

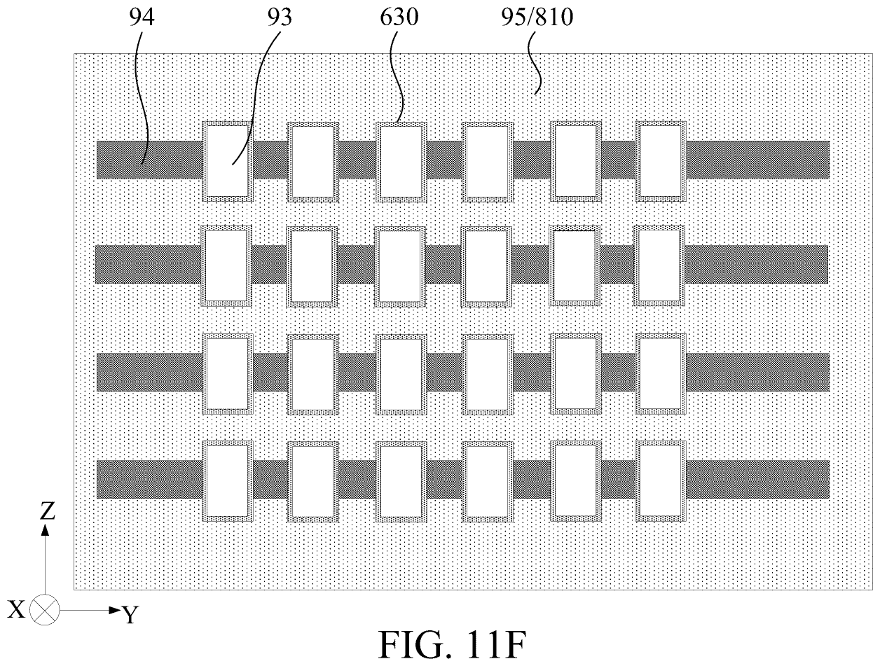

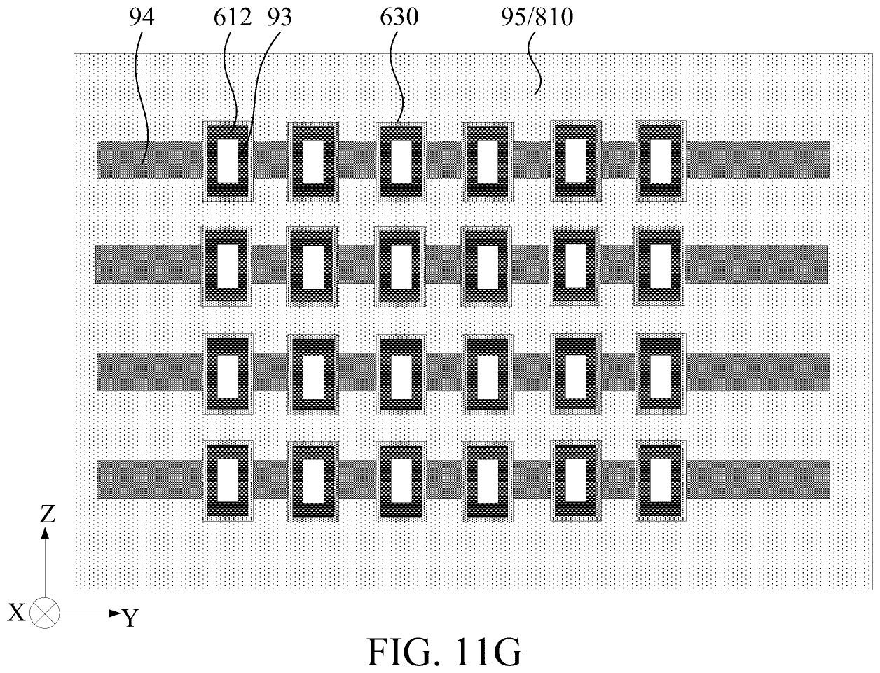

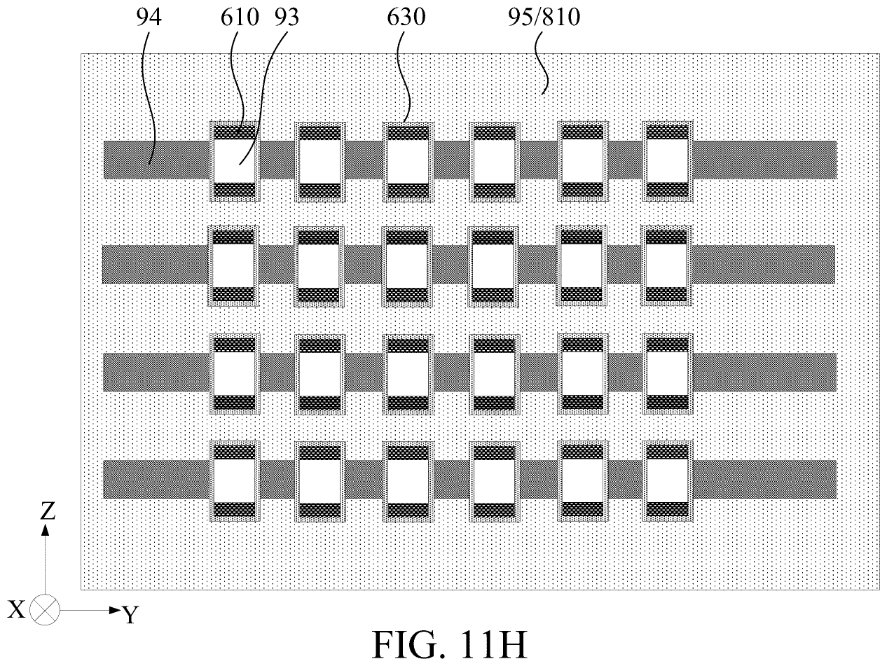

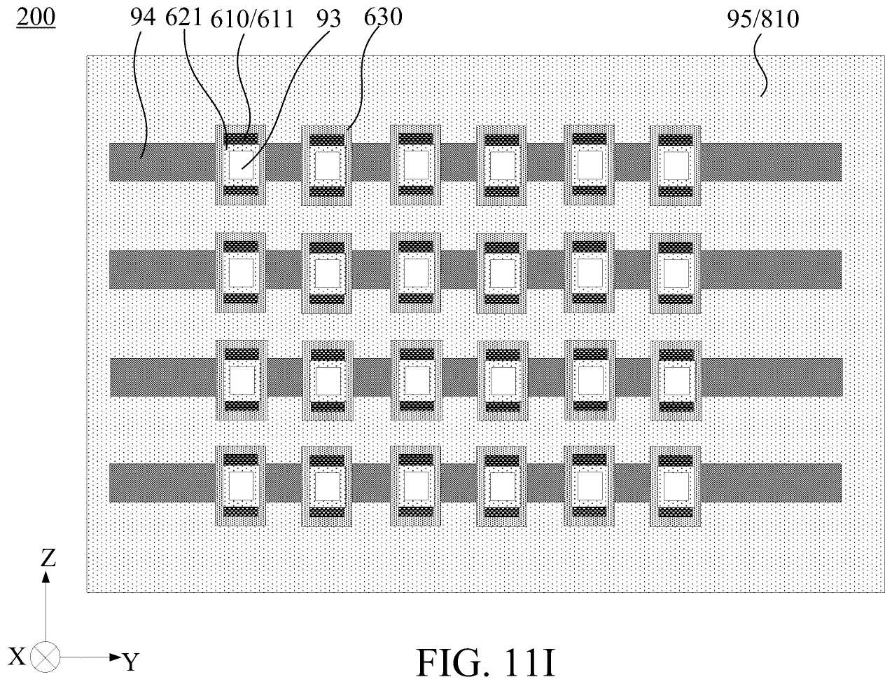

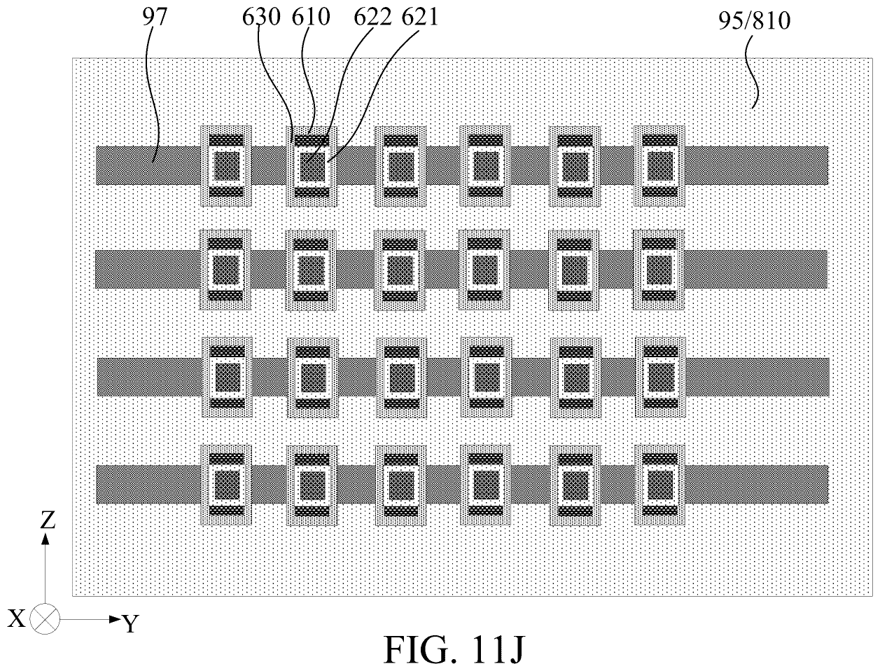

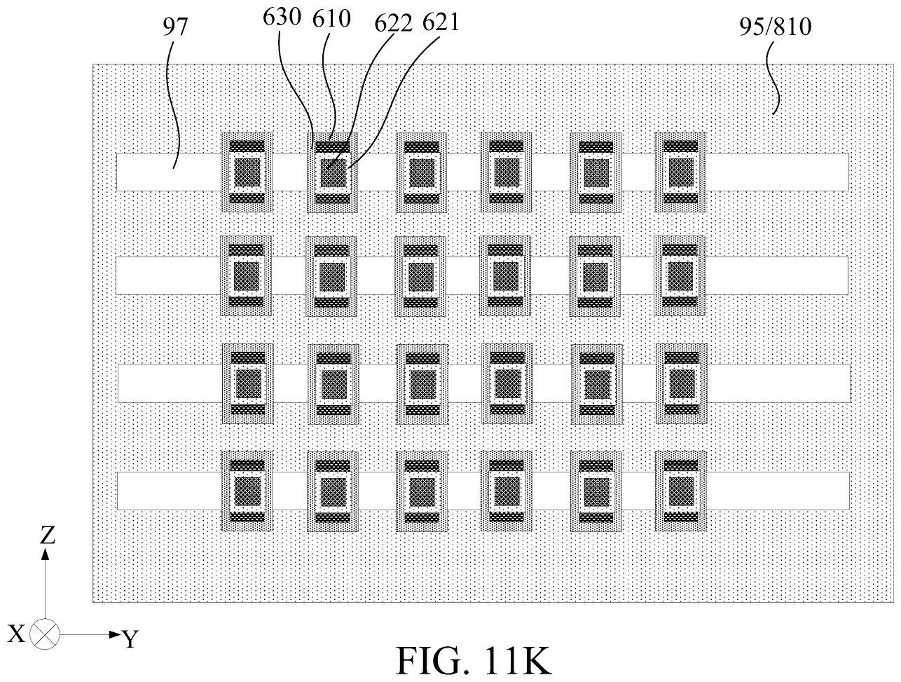

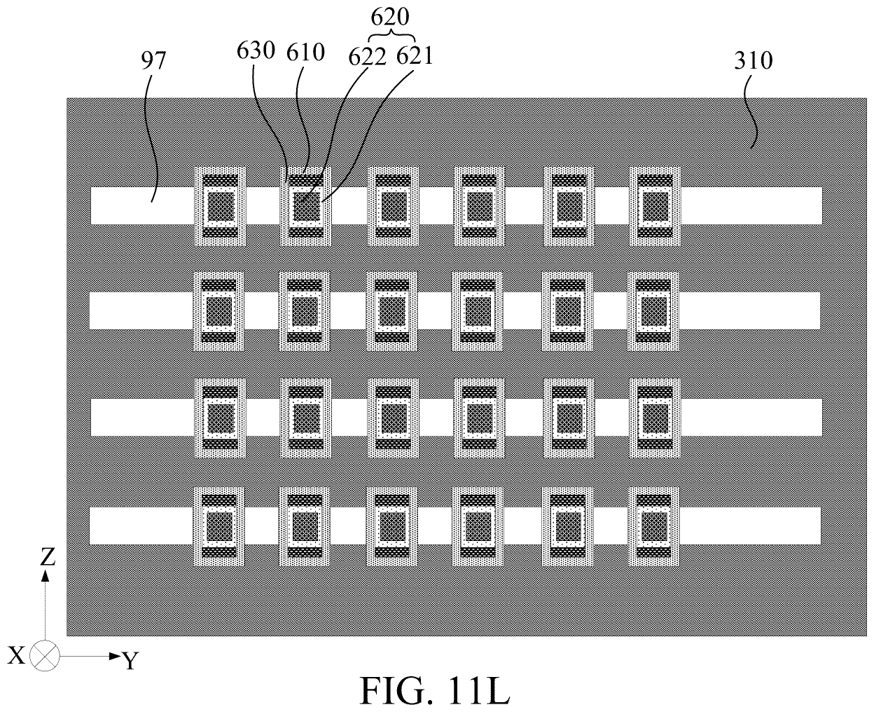

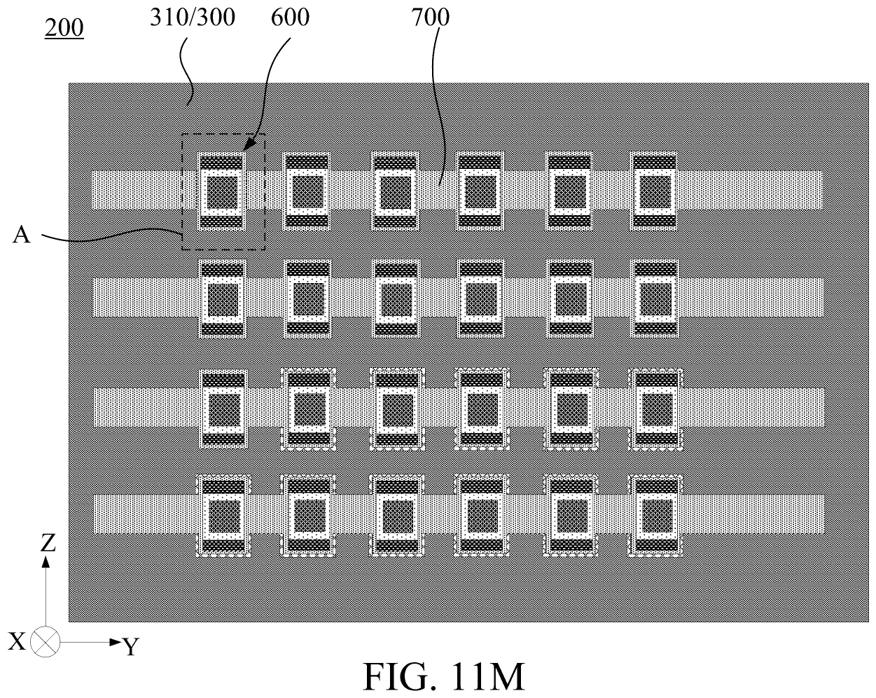

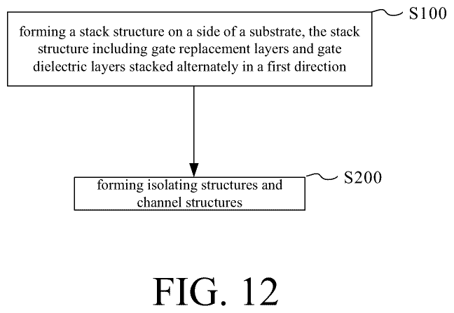

Refer to FIGS. 11A to 11M, which are some diagrams illustrating a fabrication method of a semiconductor structure in accordance with some examples. FIG. 12 is the first flow chart of a fabrication method of a semiconductor structure in accordance with some examples.

With reference to FIG. 12, the fabrication method of a semiconductor structure may include the following operations S100 and S200.

In operation S100, a stack structure is formed on a side of a substrate with the stack structure including gate replacement layers and gate dielectric layers stacked alternately in the first direction.

In operation S100, gate replacement layers 95 and gate dielectric layers 320 stacked alternately may be formed on a substrate using a thin film deposition process, that is, the gate replacement layers 95 and the gate dielectric layers 320 are stacked alternately in the first direction X.

Here, the expression “stacked alternately” indicates that a gate dielectric layer 320 is formed on the substrate, then a gate replacement layer 95 is formed on the gate dielectric layer 320 and then a gate dielectric layer 320 is formed on the gate replacement layer 95, and the above operations can be repeated.

Illustratively, the thin film deposition process may include any combination of one or more of chemical vapor deposition (CVD), physical vapor deposition (PVD), atomic layer deposition (ALD) and plating.

In operation S200, isolating structures and channel structures are formed.

With reference to FIGS. 5 and 6, the isolating structures 700 and the channel structures 600 are disposed alternately in the second direction Y and penetrate through the stack structure, the second direction being perpendicular to the first direction. The channel structure 600 includes two charge storage sections 610 disposed to be spaced from each other in the third direction and a common layer 620 located between the two charge storage sections 610. The charge storage section 610 includes a plurality of sub charge storage sections 611 disposed to be spaced from each other in the first direction and, and in the first direction, every two adjacent sub charge storage sections 611 are spaced from each other by the gate dielectric layer 320. The common layer 620 includes a tunneling layer 621 and a channel layer 622 and the tunneling layer 621 is located between the channel layer 622 and the charge storage section 610. Here, the third direction is perpendicular to the first direction and intersects the second direction.

Here, the channel structure 600 may include two charge storage sections 610 and a common layer 620 which is shared by the two charge storage sections 610 to increase the number of the charge storage sections 610 in the channel structure 600. The charge storage section 610 may be configured to form a memory cell string 400. Therefore, by disposing two charge storage sections 610 in the channel structure 600, the number of memory cell strings 400 in the channel structure 600 may be increased, increasing storage density of the semiconductor structure 200. Operation S200 will be introduced hereafter.

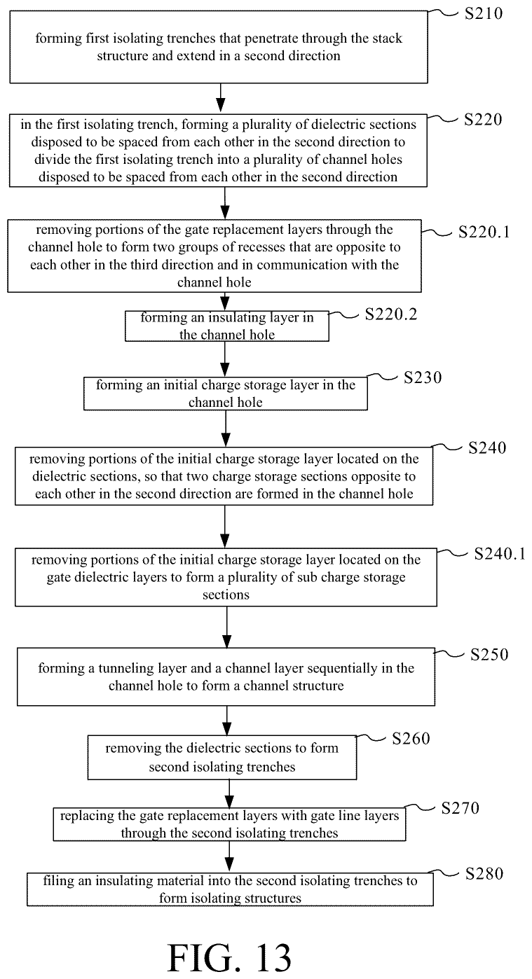

FIG. 13 is the second flow chart of a fabrication method of a semiconductor structure in accordance with some examples.

With reference to FIG. 13, in some examples, operation 200 may include the following operations S210 to S280.

With reference to FIG. 11A, in operation S210, first isolating trenches that penetrate through the stack structure and extend in the second direction are formed.

In the operation S210, the first isolating trench 91 may be etched in the stack structure 810 using a dry etching process or a wet etching process and there may be a plurality of first isolating trenches 91.

In some examples, a plurality of first isolating trenches 91 may be arranged sequentially in the third direction and spaced from each other and they may also be parallel to each other.

With continued reference to FIG. 11A, in some examples, the spacings between the two adjacent first isolating trenches 91 are the same.

With reference to FIGS. 11B to 11D, in operation S220, a plurality of dielectric sections disposed to be spaced from each other in the second direction are formed in the first isolating trench to divide the first isolating trench into a plurality of channel holes disposed to be spaced from each other in the second direction.

Here, every two adjacent channel holes 93 are spaced from each other by a dielectric section 94 and portions of surface of the dielectric section 94 may be configured to form the walls of the channel holes 93.

Illustratively, the orthogonal projection of the channel hole 93 on the substrate may have a rectangular shape and the rectangular shape may be a standard rectangular shape, i.e. two adjacent edges of the rectangular shape form a right angle. In addition, the rectangular shape may also be an approximate rectangular shape, i.e. two adjacent straight edges of the rectangular shape are perpendicular to each other, but the intersection of the two straight edges form an arc shape.

Illustratively, the rectangular shape may include a square shape or an oblong rectangular shape. The square shape may include a standard square shape or an approximate square shape and the oblong rectangular shape may include a standard oblong rectangular shape or an approximate oblong rectangular shape.

In some examples, in the stack structure 810, a plurality of channel holes 93 may be arranged in multiple rows, and the plurality of channel holes in a row may be arranged sequentially in the second direction Y. Meanwhile, the channel holes 93 in a column may be arranged sequentially in the third direction Z.

The plurality of channel holes 93 in a row are located in the first isolating trench 91 and may be arranged at the same interval.

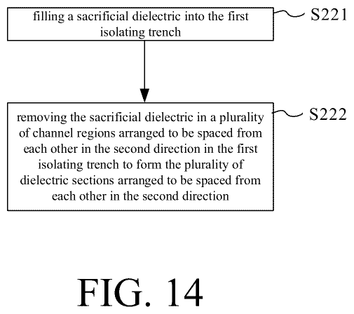

FIG. 14 is the third flow chart of a fabrication method of a semiconductor structure in accordance with some examples.

With reference to FIG. 14, operation S220 may include the following operations S221 and S222.

With reference to FIG. 11B, in operation S221, a sacrificial dielectric is filled into the first isolating trench.

The sacrificial dielectric 92 in the operation S221 may include one or more of polysilicon, silicon carbide or aluminum oxide.

In implementations in which the sacrificial dielectric 92 is polysilicon, the polysilicon may be doped with phosphorus (P) or boron (B). After being doped with boron or phosphorus, the sacrificial dielectric 92 can be etched with an increased speed when being etched.

With reference to FIGS. 11C and 11D, in operation S222, the sacrificial dielectric in a plurality of channel regions disposed to be spaced from each other in the second direction in the first isolating trench is removed to form a plurality of dielectric sections disposed to be spaced from each other in the second direction.

In the operation S222, a mask plate can be disposed on the top of the stack structure 810. The dashed box in FIG. 11C is the boundary of the mask plate and only schematically indicates the position of the mask plate without defining the specific size of the mask plate. A plurality of mask holes 98 are disposed in the mask plate and each have a strip shape. When the mask plate is disposed on the top of the stack structure, the length direction of the mask hole 98 may intersect the extending direction of the first isolating trench 91, so that portions of the sacrificial dielectric 92 may be exposed through the mask holes 98. Then the portions of the sacrificial dielectric 92 exposed through the mask holes 98 may be etched, so that a plurality of dielectric sections 94 spaced from each other are formed.

When the mask plate is disposed on the top of the stack structure 2810, the mask hole 98 extends in the third direction Z on the stack structure 810 and the extending direction of the mask hole 98 is perpendicular to the extending direction of the first isolating trench 91. With this arrangement, rectangular channel holes 93 may be formed. Here, the rectangular channel holes 93 are channel holes 93 whose orthogonal projections on the substrate are rectangular.

Illustratively, the plurality of mask holes 98 are disposed to be spaced from each other at the same interval, so that a plurality of dielectric sections 94 with the same width in the second direction Y can be formed. Additionally, since the plurality of mask holes 98 have the same width in the second direction Y, the first isolating trench 91 can be divided into a plurality of channel holes 93 arranged at the same interval by the plurality of dielectric sections 94. Here, two surfaces of the dielectric sections 94 that are opposite to each other in the second direction Y, surfaces of portions of the gate dielectric layers 320 and surfaces of portions of the gate replacement layers 95 may form the walls of a channel hole 93.

Here, the dielectric section 94 has two surfaces opposite to each other in the third direction Z and two surfaces opposite to each other in the second direction Y. The two surfaces opposite to each other in the second direction Y are configured to form walls of two channel holes 93, respectively. Two walls of the channel hole 93 that are opposite to each other in the second direction Y may be located on two dielectric sections 94, respectively.

With reference to FIG. 11D, after completion of operation S222, a plurality of channel holes 93 are formed.

With reference to FIG. 13, after operation S222, the method may further include the following operation S220.1.

In operation S220.1, portions of the gate replacement layers may be removed through the channel hole to form two groups of recesses that are in communication with the channel hole and opposite to each other in the third direction. Here, the group of recesses includes a plurality of recesses disposed to be spaced from each other in the first direction.

With reference to FIG. 11E, in the operation S220.1, the gate replacement layers 95 are disposed on both sides of the channel hole 93 in the third direction Z, and during removing of portions of the gate replacement layers 95 through the channel hole 93, the gate replacement layers 95 may be removed on both sides of the channel hole 93 to form a plurality of recesses 961 and the recesses on the same side of the channel hole 93 in the third direction Z may form a group of recesses 96.

The recess 961 may be enclosed by the gate dielectric layer 320 and the gate replacement layer 95. The recess 961 may include two surfaces opposite to each other in the first direction X as well as a recess bottom and a recess opening opposite to each other in the third direction Z. The surfaces of the recess 961 in the first direction X may be formed by two adjacent gate dielectric layers 320, the recess bottom of the recess 961 may be formed by the gate replacement layer 95 and the recess opening may be located at the side wall of the channel hole 93, so that the recess 961 may be in communication with the channel hole 93.

In the two groups of recesses corresponding to a channel hole 93, a recess 961 in a group of recesses 96 may correspond to another recess 961 in another group of recesses 96, so that orthogonal projections in the third direction Z of the above two recesses 961 may cover the same gate replacement layer 95.

Here, the two groups of recesses 96 corresponding to a channel hole 93 are two groups of recesses in which recesses 961 are all in communication with the same channel hole 93.

Additionally, since the gate replacement layers 95 and the gate dielectric layers 320 are disposed alternately in the first direction X, two adjacent recesses 961 in the first direction X in a group of recesses 96 may have a gate dielectric layer 320 disposed therebetween.

With reference to FIG. 11F, after operation S220, i.e. after operation S222, the method may further include operation S220.2 in which an insulating layer 630 is formed in the channel hole 93. The insulating layer 630 may be formed by a deposition process.

Here, the insulating layer 630 may cover the walls of the channel hole 93. That is to say, the insulating layer 630 may cover two surfaces of the dielectric section 94 that are opposite to each other in the second direction Y, surfaces of portions of the gate dielectric layers 320 and surfaces of portions of the gate replacement layers 95.

In case that the fabrication method further includes the operation S220.1, when the insulating layer 630 is formed in the channel hole 93, the insulating layer 630 may also be formed in the plurality of recesses 961 in the groups of recesses 96.

In operation S230, an initial charge storage layer is formed in the channel hole.

With reference to FIG. 11G, in operation S230, the initial charge storage layer 612 may be formed in the channel hole 93 using a deposition process. Here, the initial charge storage layer 612 may cover the walls of the channel hole 93.

Here, in operation S230, the initial charge storage layer 612 may cover two surfaces of the dielectric section 94 that are opposite to each other in the second direction Y, surfaces of portions of the gate dielectric layers and surfaces of portions of the gate replacement layers 95.

In case that the fabrication method further includes the operation S220.1, when the initial charge storage layer 612 is formed in the channel hole 93, portions of the initial charge storage are located in the plurality of recesses 961, as shown in FIG. 11E.

When the initial charge storage layer 612 is formed in the channel hole 93, portions of the initial charge storage layer 612 may fill up the recesses 961, or fill the recesses 961 partially, and portions of the initial charge storage layer 612 are located on portions of the gate dielectric layers 320 and portions of the dielectric sections as inner walls of the channel hole 93.

The operation of forming an insulating layer 630 in the channel hole 93 may be performed before operation S230. It is to be understood that the initial charge storage layer 612 may be formed on the surface of the insulating layer 630 away from the walls of the channel hole 93.

In operation S240, portions of the initial charge storage layer located on the dielectric sections are removed, so that two charge storage sections opposite to each other in the second direction are formed in the channel hole.

With reference to FIGS. 11G and 11H, in operation S240, after removing portions of the charge storage layer 612 that are located on the portions of the dielectric section 94 used to form walls of the channel hole 93, i.e., the charge storage layer 612 located on the two opposite sides of the dielectric section 94 in the second direction Y is removed, portions of the initial charge storage layer 612 located on the gate dielectric layers 320 and the gate replacement layers 95 remain, so that the initial charge storage layer 612 covering the inner walls of the channel hole 93 may be divided into two charge storage sections 61 opposite to each other in the second direction Y.

In case that the fabrication method further includes the operation S220.1, the portions of the initial charge storage layer 612 located on the gate dielectric layers 320 and the gate replacement layers 95 may also include the portions of the initial charge storage layer 612 located in the recesses 961. That is, after operation S240, after removing the portions of the initial charge storage layer 612 located on the dielectric sections 94, the portions of the initial charge storage layer 612 located in the recesses 961 may remain.

By removing the portions of the initial charge storage layer 612 located on the dielectric sections 94, two charge storage sections 610 may be formed. A charge storage section 610 may be configured to form a memory cell string. Therefore, by disposing two charge storage sections 610 in a channel structure 600, the number of memory cell strings in the channel structure may be increased, thereby increasing storage density of the semiconductor structure 200.

After operation S230, the fabrication method may further include operation S240.1, in which portions of the initial charge storage layer located on portions of the gate dielectric layers may be removed to form a plurality of sub charge storage sections.

Since surfaces of portions of the gate dielectric layers 320 (as shown in FIG. 10) may be configured to form inner walls of the channel hole 93, removing portions of the initial charge storage layer 612 located on portions of the gate dielectric layers 320 is removing the portions of the initial charge storage layer 612 on the surfaces of the gate dielectric layers 320 that are configured to form inner walls of the channel hole 93.

After operation S240.1, i.e., after removing the portions of the initial charge storage layer 612 located on portions of the gate dielectric layers 320, the charge storage section 610 covering the inner walls of the channel hole 93 may be divided into a plurality of sub charge storage sections 611 disposed to be spaced from each other in the first direction X.

In case that the fabrication method further includes the operation S220.1, after operation S240.1, i.e. after removing the portions of the initial charge storage layer 612 located on the gate dielectric layers 320, portions of the initial charge storage layer 612 located in the recesses 961 can remain to serve as sub charge storage sections 611.

Here, the sub charge storage section 611 may fill up the recess 961, or fill the recess 961 partially, i.e. not fill up the recess 961.

Since two adjacent sub charge storage sections 611 in the first direction X are spaced from each other by a gate dielectric layer 320, two adjacent sub charge storage sections 611 in the first direction X are spaced from each other to inhibit charges from diffusing from a sub charge storage section 611 to the adjacent sub charge storage section 611 in the first direction X.

In some examples, the portions of the initial charge storage layer 612 on the gate dielectric layers 320 and the portions of the initial charge storage layer 612 on the dielectric sections 94 may be removed simultaneously.

By removing the portions of the initial charge storage layer 612 on the gate dielectric layers 320 and the portions of the initial charge storage layer 612 on the dielectric sections 94 simultaneously, operation S240.1 can be performed in one process.

After formation of the sub charge storage sections 611, a common layer 620 can be formed in the channel hole 93. In some examples, the common layer 620 may include a tunneling layer 621 and a channel layer 622. Here, the channel layer 622 may be a solid pillar.

In operation S250, the tunneling layer and the channel layer are formed sequentially in the channel hole to form a channel structure.

With reference to FIG. 11I, in operation S250, after forming a tunneling layer 621 in the channel hole 93, the tunneling layer 621 may be located on the surfaces of the sub charge storage sections 611 and surfaces of the insulating layers 630.

With reference to FIG. 11J, after forming the tunneling layer 621, a channel layer 622 may be formed.

In some other examples, the common layer 620 may further include a supporting section 623 that may be located inside the channel layer 622. Here, the channel layer 622 may surround the supporting section 623 that can provide support to the channel structure 600.

Here, the operation of forming the common layer 620 in the channel hole 93 may include forming the tunneling layer 621, the channel layer 622 and the supporting section 623 sequentially in the channel hole.

In case that the recesses 961 are not filled up by the sub charge storage sections 610, the charge storage sections 610 and portions of the tunneling layer 621 are all located in the recesses 961.

After formation of the common layer 620, fabrication of the channel structure 600 is completed.

The fabrication method of the channel structure 600 has been described above, and next the fabrication method of the isolating structure 700 will be described.

After forming the tunneling layer 621 and the channel layer 622 sequentially in the channel hole 93 in operation S250, the following operations S260 to S280 may also be included.

In operation S260, the dielectric sections are removed to form the second isolating trenches.

With reference to FIGS. 11K and 11L, in operation S260, the dielectric sections 94 may be removed by a wet etching process. After removing the dielectric sections 94, the second isolating trenches 97 penetrating the stack structure may be formed.

The number of the second isolating trenches 97 may be the same as the number of the dielectric sections 94. A plurality of second isolating trenches 97 are disposed to be spaced from each other in the second direction Y and a channel structure 600 is disposed between two adjacent second isolating trenches 97 in the second direction Y. In the third direction Z, a plurality of second isolating trenches 97 are also disposed to be spaced from each other and the stack structure 810 is disposed between two adjacent second isolating trenches 97.

In some examples, the dielectric section 94 may be formed of and therefore have the same material as the sacrificial dielectric. When the sacrificial dielectric is polysilicon, the sacrificial dielectric is doped with B or P, so that the material used to form the dielectric sections 94 has an etching selection ratio higher than that of the material used to form the channel layer 622 to prevent the channel layer 622 from being damaged during removing of the dielectric sections 94 and thus facilitate improvement of the reliability of the channel structure 600.

With continued reference to FIG. 11K, after formation of the second isolating trenches 97, the gate replacement layers 95 may be exposed through the second isolating trenches 97.

In operation S270, the gate replacement layers may be replaced with gate line layers through the second isolating trenches.

Next, the process of forming the gate line layers 310 will be described.

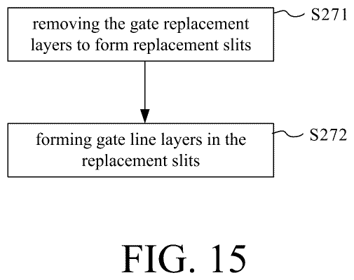

FIG. 15 is the fourth flow chart of a fabrication method of a semiconductor structure in accordance with some examples.

The operation S270 may include the following operations S271 and S272.

In operation S271, gate replacement layers are removed to form replacement slits.

In operation S272, gate line layers are formed in the replacement slits.

Here, in operation S271, the gate replacement layers 95 in the stack structure 810 may be removed using isotropic etching through the second isolating trenches 97 to form the replacement slits 820. Here, the channel structures 600 can be supported by the plurality of gate dielectric layers 320. Here, the isotropic etching may use selective wet etching or vapor etching.

Here, refer back to FIG. 10 for replacement slits 820. It is to be noted that, in FIG. 10, the dashed box with a label 820 is only used to indicate the position of a replacement slit 820 and does not represent the boundary of the replacement slit 820.

Additionally, the gate dielectric layers 320 (as shown in FIG. 8) and the gate replacement layers 95 are etched at different speeds under the same process conditions, so that the gate dielectric layers 320 will not be damaged during removing of the gate replacement layers 95.

During the process of replacing the gate replacement layers 95 with gate line layers 310, the plurality of second isolating trenches 97 may add a path to remove the gate replacement layers 95 and form the gate line layers 310 so as to improve replacement efficiency.

In some examples, in operation S272, before forming gate line layers in the replacement slits 820, the operation of forming the high dielectric constant layers 800 in the replacement slits 820 may be included.

Here, the high dielectric constant layers 800 may be formed before the formation of the gate line layers 310, the high dielectric constant layer 800 may be located between two adjacent gate dielectric layers 320. Here, a portion and another portion of the high dielectric constant layer 800 are located between the gate line layer 310 and the gate dielectric layer 320.

In addition, the semiconductor structure 200 may further include TiN layers 900 (as shown in FIG. 8) that may be formed before the formation of the gate line layers 310. Here, the TIN layer 900 is located between the high dielectric constant layer 800 and the gate line layer 310.

In another example, the high dielectric constant layers 800 can also be formed before operation S230 in which the initial charge storage layers 612 are formed in the channel holes 93. Here, high dielectric constant layers 800 are formed in the channel holes 93, so that the high dielectric constant layers 800 cover the surfaces of the gate dielectric layers 320 exposed by the channel holes 93 and the surfaces of the gate replacement layers 95 and the gate dielectric layers 320 exposed by the groups of recesses 96. In this example, the area of the high dielectric constant layers 800 is relatively small, which facilitates more uniform thickness of the high dielectric constant layers 800. Here, refer to FIGS. 9 and 10 for structure of the semiconductor structure 200 formed. Here, the orthogonal projection of the high dielectric constant layer 800 in the third direction Z may cover the gate dielectric layers 320 and the gate line layers 310 and the orthogonal projection of the high dielectric constant layer 800 in the second direction Y may cover all the isolating structures 700.

However, in some other examples, after forming high dielectric constant layer 800 in the channel hole 93, the high dielectric constant layer 800 may cover inner walls of the channel hole 93 and inside of the recesses 961. The portions of the high dielectric constant layer 800 located on the dielectric sections 94 and the gate dielectric layers 320 may be removed, so that the orthogonal projection of the high dielectric constant layer 800 in the third direction Z may only cover the gate line layer 310.

In operation S280, the second isolating trenches are filled with an insulating material to form isolating structures.

With reference to FIG. 11M, the insulating material is filled into the second isolating trenches 97 using a deposition process. During deposition of the insulating material, the insulating material not only fills the second trenches 97, but also covers the top of the stack structure 810. Here, the top of the stack structure 810 refers to the surface of the stack structure 810 away from the substrate and also has an oxide layer formed thereon.

In some examples, after operation S280, a chemical mechanical polishing can be performed on the oxide layer, so that the stack structure 810 have a flat surface, which can facilitate formation of peripheral circuits on the top of the stack structure 810.

Until now, the fabrication of the semiconductor structure 200 is completed. That is, after operation S80, the stack structure 810 may also be referred to as a memory stack structure 300.

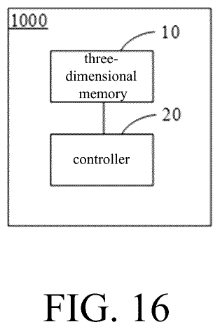

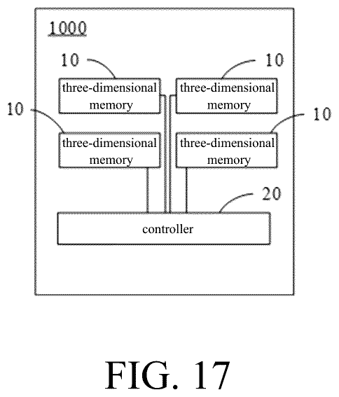

FIG. 16 is a block diagram of a memory system in accordance with some examples. FIG. 17 is a block diagram of a memory system in accordance with some other examples.

With reference to FIGS. 16 and 17, some examples of the present disclosure further provide a memory system 1000. The memory system 1000 includes a controller 20 and a three-dimensional memory 10 as described in some examples above. The controller 20 is coupled to the three-dimensional memory 10 to control its data storage.

The memory system 1000 can be integrated into various types of storage devices, for example, be included in the same package such as a universal flash storage (UFS) or an embedded multi-media card (eMMC) package. That is, the memory system 1000 may be applied to and packaged into various electronic products such as a mobile phone (e.g., a cellphone), a desktop computer, a tablet computer, a laptop computer, a server, a vehicle-mounted device, a gaming console, a printer, a positioning device, a wearable device, a smart sensor, a mobile power source, a virtual reality (VR) device, an augmented reality (AR) device, or any other suitable electronic device having storage therein.

In some examples, with reference to FIG. 16, the memory system 1000 includes a controller 20 and a three-dimensional memory 10 and may be integrated into a memory card.

The memory card may include any one of a PC card (the personal computer memory card international association, PCMCIA), a compact flash (CF) card, a smart media (SM) card, a memory stick, a multimedia card (MMC), a secure digital (SD) memory card and a UFS.

In some other examples, with reference to FIG. 17, the memory system 1000 includes a controller 20 and a plurality of three-dimensional memories and is integrated into a solid state drive (SSD).

In some examples, the controller 20 of the memory system 1000 is configured to operate in a low duty-cycle environment like an SD card, a CF card, a universal serial bus (USB) flash drive or any other medium for use in an electronic device, such as a personal computer, a digital camera, a mobile phone, etc.

In some other examples, the controller 20 is configured to operate in a high duty-cycle environment like an SSD or an eMMC, used as a data storage for a mobile device such as a smart phone, a tablet computer or a laptop computer, and an enterprise storage array.

In some examples, the controller 20 can be configured to manage the data stored in the 3D memory 10 and communicates with an external device (e.g., a host). In some examples, the controller 20 can also be configured to control operations of the 3D memory 10, such as read, erase, and program operations. In some examples, the controller 20 can also be configured to manage various functions with respect to the data stored or to be stored in the 3D memory 10, including at least one of bad-block management, garbage collection, logical-to-physical address conversion and wear leveling. In some examples, the controller 20 is further configured to process error correction codes (ECCs) with respect to the data read from or written to the 3D memory 10.

Of course, the controller 20 may also perform any other suitable functions, for example, formatting the three-dimensional memory 10. For example, the controller 20 can communicate with an external device (e.g., a host) according to at least one of various interface protocols.

It is to be noted that the interface protocol includes at least one of a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol and a Firewire protocol.

Some examples of the present disclosure further provide an electronic device. The electronic device may be any one of a cellphone, a desktop computer, a tablet computer, a laptop computer, a server, a vehicle-mounted device, a wearable device (e.g., a smart watch, a smart bracelet, smart glasses), a mobile power source, a gaming console and a digital multimedia player.

The electronic device may include the memory system 1000 and may further include any one of a central processing unit (CPU) and a cache.

Examples of the present disclosure provide a semiconductor structure and a fabrication method thereof and are intended to solve the problem of charge diffusion of channel structures.

To this end, examples of the present disclosure employ the following technical solutions.

In one aspect, a semiconductor structure is provided. The semiconductor structure includes a memory stack structure and isolating structures and channel structures that are disposed alternately in a second direction. The memory stack structure includes gate line layers and gate dielectric layers stacked alternately in a first direction. Both the isolating structures and the channel structures penetrate through the memory stack structure. The second direction is perpendicular to the first direction. The channel structure includes two charge storage sections disposed to be spaced from each other in the third direction and a common layer located between the two charge storage sections. The charge storage section includes a plurality of sub charge storage sections disposed to be spaced from each other in the first direction, and in the first direction, every two adjacent sub charge storage sections are spaced from each other by the gate dielectric layer. The common layer includes a tunneling layer and a channel layer and the tunneling layer is located between the channel layer and the charge storage section. The third direction is perpendicular to the first direction and intersects the second direction.

In the semiconductor structure provided by the examples of the present disclosure, the gate line layers and the channel structure may be configured to form a memory cell string. The channel structure includes two charge storage sections disposed to be spaced from each other in the third direction and a common layer located between the two charge storage sections. A charge storage section may be used to form a memory cell string and a channel structure includes two charge storage sections. Therefore, a channel structure may be configured to form two memory cell strings to increase the number of the memory cell strings and thus improve the storage density of the semiconductor structure. The charge storage section includes a plurality of sub charge storage sections disposed to be spaced from each other in the first direction. Every two adjacent sub charge storage sections are spaced from each other by the gate dielectric layer. Therefore, two adjacent sub charge storage sections in the first direction are isolated from each other to inhibit charges from diffusing from a sub charge storage section to another sub charge storage section.

In some examples, the channel structure includes two first planes opposite to each other in the second direction and two second planes opposite to each other in the third direction. The first plane is connected to the two second planes on both sides in the second direction, and the second plane is connected to the two first planes on both sides in the third direction.

In some examples, an orthogonal projection of the channel structure in the first direction has a rectangular shape.

In some examples, a width of the channel structure in the third direction is larger than a width of the channel structure in the second direction.

In some examples, a width of the isolating structure in the third direction is smaller than a width of the channel structure in the third direction, the isolating structure faces the common layer in the second direction, and the charge storage section and the isolating structure are staggered in the second direction.

In some examples, the channel structure further comprises an insulating layer surrounding the charge storage sections and the common layer.

In some examples, the semiconductor structure further comprises high dielectric constant layers, each of which is located between the channel structure and the isolating structures and surrounds the channel structure.

In some other examples, the high dielectric constant layer is located between the gate line layer and the gate dielectric layer and between the gate line layer and the channel structure.

In some examples, the common layer further comprises a supporting section surrounded by the channel layer.

In another aspect, a fabrication method of a semiconductor structure is provided, the method comprising:
forming a stack structure on a side of a substrate, the stack structure including gate replacement layers and gate dielectric layers stacked alternately in a first direction; and
forming isolating structures and channel structures that are disposed alternately in a second direction and penetrate through the stack structure, the second direction being perpendicular to the first direction, wherein the channel structure includes two charge storage sections disposed to be spaced from each other in the third direction and a common layer located between the two charge storage sections, the charge storage section comprises a plurality of sub charge storage sections disposed to be spaced from each other in the first direction, and in the first direction, every two adjacent sub charge storage sections are spaced from each other by the gate dielectric layer, the common layer comprises a tunneling layer and a channel layer and the tunneling layer is located between the channel layer and the charge storage section, the third direction being perpendicular to the first direction and intersecting the second direction.

In some examples, forming the isolating structures and the channel structures comprises:
forming first isolating trenches that penetrate through the stack structure and extend in the second direction;
forming a plurality of dielectric sections disposed to be spaced from each other in the second direction in the first isolating trench to divide the first isolating trench into a plurality of channel holes disposed to be spaced from each other in the second direction;
forming an initial charge storage layer in the channel hole;
removing portions of the initial charge storage layer located on the dielectric sections, so that two charge storage sections opposite to each other in the second direction are formed in the channel hole; and
forming the tunneling layer and the channel layer sequentially in the channel hole.

In some examples, before forming the tunneling layer and the channel layer sequentially in the channel, the method further comprises:
removing portions of the initial charge storage layer located on the gate dielectric layers to form a plurality of sub charge storage sections.

In some examples, before forming the initial charge storage layer in the channel hole, the method further comprises:
removing portions of the gate replacement layers through the channel hole to form two groups of recesses that are in communication with the channel hole and opposite to each other in the third direction, wherein the group of recesses comprises a plurality of recesses disposed to be spaced from each other in the first direction, and
when the initial charge storage layer is formed in the channel hole, portions of the initial charge storage layer are located in the plurality of recesses.

In some examples, the portions of the initial charge storage layer located on the gate dielectric layers and the portions of the initial charge storage layer located on the dielectric sections are removed simultaneously.

In some examples, before forming the initial charge storage layer in the channel hole, the method further comprises:
forming an insulating layer in the channel hole.

In some examples, forming, in the first isolating trench, the plurality of dielectric sections disposed to be spaced from each other in the first direction to divide the first isolating trench into a plurality of channel holes disposed to be spaced from each other in the first direction comprises:
filling a sacrificial dielectric into the first isolating trench; and
removing the sacrificial dielectric in a plurality of channel regions disposed to be spaced from each other in the second direction in the first isolating trench to form the plurality of dielectric sections disposed to be spaced from each other in the second direction.

In some examples, the sacrificial dielectric includes one or more of polysilicon, silicon carbide or aluminum oxide.

In some examples, before forming the initial charge storage layer in the channel hole, the method further comprises:
forming high dielectric constant layers in the channel hole.

In some examples, after forming the tunneling layer and the channel layer sequentially in the channel, the method further comprises:
removing the dielectric sections to form second isolating trenches;
replacing the gate replacement layers with gate line layers through the second isolating trenches; and
filling the second isolating trenches with an insulating material to form isolating structures.

In some examples, replacing the gate replacement layers with gate line layers through the second isolating trenches comprises:
removing the gate replacement layers to form replacement slits; and
forming the gate line layers in the replacement slits; and wherein
before forming gate line layers in the replacement slits, the method further comprises:
forming high dielectric constant layers in the replacement slits.

It can be understood that the beneficial effects of the fabrication method of the semiconductor structure provided by the examples of present disclosure can be referred to for the beneficial effects of the semiconductor structure above, and will not repeated.

What have been described above are only specific implementations of the present disclosure. However, the scope of the present disclosure is not limited thereto, and variations or substitutions that easily occur to those skilled in the art within the technical scope disclosed by the present disclosure should be encompassed in the scope claimed by the present disclosure. Therefore, the scope of the present disclosure should be determined by the scope of the claims.

What is claimed is:

1. A semiconductor structure, comprising:
a memory stack structure comprising gate line layers and gate dielectric layers stacked alternately in a first direction; and
isolating structures and channel structures that are disposed alternately in a second direction and penetrate through the memory stack structure, the second direction being perpendicular to the first direction;
wherein the channel structure comprises two charge storage sections disposed to be spaced from each other in a third direction and a common layer located between the two charge storage sections, the charge storage section comprises a plurality of sub charge storage sections disposed to be spaced from each other in the first direction, and in the first direction, every two adjacent sub charge storage sections are spaced from each other by the gate dielectric layer, the common layer comprises a tunneling layer and a channel layer, and the tunneling layer is located between the channel layer and the charge storage section, the third direction being perpendicular to the first direction and intersecting the second direction.

2. The semiconductor structure of claim 1, wherein the channel structure comprises two first planes opposite to each other in the second direction and two second planes opposite to each other in the third direction, the first plane is connected to the two second planes on both sides in the second direction, and the second plane is connected to the two first planes on both sides in the third direction.

3. The semiconductor structure of claim 2, wherein an orthogonal projection of the channel structure in the first direction has a rectangular shape.

4. The semiconductor structure of claim 1 wherein a width of the channel structure in the third direction is larger than a width of the channel structure in the second direction.

5. The semiconductor structure of claim 1, wherein a width of the isolating structure in the third direction is smaller than a width of the channel structure in the third direction, the isolating structure faces the common layer in the second direction, and the charge storage section and the isolating structure are staggered in the second direction.

6. The semiconductor structure of claim 1, wherein the channel structure further comprises an insulating layer surrounding the charge storage sections and the common layer.

7. The semiconductor structure of claim 1, further comprising high dielectric constant layers, each of which is located between the channel structure and the isolating structure and surrounds the channel structure.

8. The semiconductor structure of claim 1, further comprising:
high dielectric constant layers, each of which is located between the gate line layer and the gate dielectric layer and between the gate line layer and the channel structure.

9. The semiconductor structure of claim 1, wherein the common layer further comprises a supporting section surrounded by the channel layer.

10. A fabrication method of a semiconductor structure, comprising:
forming a stack structure on a side of a substrate, the stack structure comprising gate replacement layers and gate dielectric layers stacked alternately in a first direction; and
forming isolating structures and channel structures that are disposed alternately in a second direction and penetrate through the stack structure, the second direction being perpendicular to the first direction, wherein the channel structure comprises two charge storage sections disposed to be spaced from each other in the third direction and a common layer located between the two charge storage sections, the charge storage section comprises a plurality of sub charge storage sections disposed to be spaced from each other in the first direction, and in the first direction, every two adjacent sub charge storage sections are spaced from each other by the gate dielectric layer, the common layer comprises a tunneling layer and a channel layer, and the tunneling layer is located between the channel layer and the charge storage section, the third direction being perpendicular to the first direction and intersecting the second direction.

11. The fabrication method of claim 10, wherein forming the isolating structures and the channel structures comprises:
forming first isolating trenches that penetrate through the stack structure and extend in the second direction;
in the first isolating trench, forming a plurality of dielectric sections disposed to be spaced from each other in the second direction to divide the first isolating trench into a plurality of channel holes disposed to be spaced from each other in the second direction;
forming an initial charge storage layer in the channel hole;
removing portions of the initial charge storage layer located on the dielectric sections, so that two charge storage sections opposite to each other in the second direction are formed in the channel hole; and
forming the tunneling layer and the channel layer sequentially in the channel hole.

12. The fabrication method of claim 11, wherein before forming the tunneling layer and the channel layer sequentially in the channel hole, the method further comprises:
removing portions of the initial charge storage layer located on the gate dielectric layers to form a plurality of sub charge storage sections.

13. The fabrication method of claim 12, wherein before forming the initial charge storage layer in the channel hole, the method further comprises:
removing portions of the gate replacement layers through the channel hole to form two groups of recesses that are in communication with the channel hole and opposite to each other in the third direction, wherein the group of recesses comprises a plurality of recesses disposed to be spaced from each other in the first direction, and
when the initial charge storage layer is formed in the channel hole, portions of the initial charge storage layer are located in the plurality of recesses.

14. The fabrication method of claim 13, wherein the portions of the initial charge storage layer on the gate dielectric layers and the portions of the initial charge storage layer on the dielectric sections are removed simultaneously.

15. The fabrication method of claim 11, wherein before forming the initial charge storage layer in the channel hole, the method further comprises:
forming an insulating layer in the channel hole.

16. The fabrication method of claim 11, wherein
forming, in the first isolating trench, the plurality of dielectric sections disposed to be spaced from each other in the first direction to divide the first isolating trench into the plurality of channel holes disposed to be spaced from each other in the first direction comprises:
filling a sacrificial dielectric into the first isolating trench; and
removing the sacrificial dielectric in a plurality of channel regions disposed to be spaced from each other in the second direction in the first isolating trench to form the plurality of dielectric sections disposed to be spaced from each other in the second direction.

17. The fabrication method of claim 16, wherein the sacrificial dielectric includes one or more of polysilicon, silicon carbide or aluminum oxide.

18. The fabrication method of claim 11, wherein before forming the initial charge storage layer in the channel hole, the method further comprises:
forming high dielectric constant layers in the channel hole.

19. The fabrication method of claim 11, wherein after forming the tunneling layer and the channel layer sequentially in the channel hole, the method further comprises:
removing the dielectric sections to form second isolating trenches;
replacing the gate replacement layers with gate line layers through the second isolating trenches; and
filling the second isolating trenches with an insulating material to form isolating structures.

20. The fabrication method of claim 19, wherein replacing the gate replacement layers with gate line layers through the second isolating trenches comprises:
removing the gate replacement layers to form replacement slits; and
forming the gate line layers in the replacement slits, wherein
before forming gate line layers in the replacement slits, the method further comprises:
forming high dielectric constant layers in the replacement slits.
